(19) United States
(12) Patent Application Publication
(10) Pub. No.: US 2025/0293215 A1
(43) Pub. Date: Sep. 18, 2025

(54) LIGHT MIXING ARRANGEMENTS IN MULTIPLE-CHIP LIGHT-EMITTING DIODE PACKAGES

(71) Applicant: CreeLED, Inc., Durham, NC (US)

(72) Inventors: Joseph M. Favale, JR., Cary, NC (US); Robert David Schmidt, Wake Forest, NC (US)

(21) Appl. No.: 18/604,866

(22) Filed: Mar. 14, 2024

(51) Int. Cl. H01L 25/075; H01L 33/48; H01L 33/58

(52) U.S. Cl. CPC H01L 25/0753; H10H 20/8506; H10H 20/855

(57) ABSTRACT

Light-emitting diode (LED) packages and more particularly light mixing arrangements in LED packages are disclosed. LED packages include multiple LED chips arranged within a single recess or cavity and a single corresponding lens. Light mixing arrangements include LED chip layouts, lens structures, and/or cladding layers for lens structures. LED packages are disclosed with reduced full width half maximum values and improved uniformity in far field pattern emissions by reducing lensing effects of multiple LED chips in a single cavity. A figure of merit is described that defines a color quality index metric that characterizes color quality and uniformity of far field emissions in multiple-color and multiple-chip LED packages.

### FIELD OF THE DISCLOSURE

The present disclosure relates to light-emitting diode (LED) packages and more particularly to light mixing arrangements in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. As LED technology continues to be developed for ever-evolving modern applications, challenges exist in keeping up with operating demands for LED packages and related elements of LED packages.

LED packages that contain more than one LED chip, particularly LED packages with different colored LED chips, can have far field patterns (FFPs) that have different color intensities depending on the angle at which the LED package is viewed. This is detrimental to the color uniformity of LED displays and other applications as the color is observed to change with viewing angle.

The art continues to seek improved LEDs and solid-state lighting devices having desirable illumination characteristics capable of overcoming challenges associated with conventional lighting devices.

### SUMMARY

The present disclosure relates to light-emitting diode (LED) packages and more particularly to light mixing arrangements in LED packages. LED packages include multiple LED chips arranged within a single recess or cavity and a single corresponding lens. Light mixing arrangements include LED chip layouts, lens structures, and/or cladding layers for lens structures. LED packages are disclosed with reduced full width half maximum values and improved uniformity in far field pattern emissions by reducing lensing effects of multiple LED chips in a single cavity. A figure of merit is described that defines a color quality index metric that characterizes color quality and uniformity of far field emissions in multiple-color and multiple-chip LED packages.

In one aspect, an LED package comprises: a support structure forming a recess; one or more LED chips within the recess; a lens over the recess; and a cladding layer on a portion of the lens that is above the support structure, the cladding layer forming a coating on a surface of the lens. In certain embodiments, the lens comprises a lens base that extends from the support structure and a lens upper portion that forms a curved surface above the lens base. In certain embodiments, the lens base forms a circular cross-section. In certain embodiments, the lens base forms a rectellipse cross-section. In certain embodiments, the cladding layer is positioned on a surface of the lens along the lens base. In certain embodiments, the surface of the lens along the lens base where the cladding layer is positioned is spaced from a topmost surface of the support structure. The LED package may further comprise an additional cladding layer on a surface of the lens along the lens upper portion. In certain embodiments, the cladding layer comprises a light-reflective material. In certain embodiments, the cladding layer comprises a light-absorbing material. In certain embodiments, the one or more LED chips comprise at least three LED chips configured to generate a plurality of peak wavelengths, and the lens comprises a lens base that extends from the support structure and a lens upper portion that forms a curved surface above the lens base. In certain embodiments, a far field pattern of aggregate emissions from the at least three LED chips has a full width half maximum of less than 50. In certain embodiments, a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of: raw far field pattern data for each LED chip; a noise corrected luminous intensity data of the raw far field pattern data for each LED chip; a percent difference relative to center for all nonzero noise corrected luminous intensity data; areas under a curve for all absolute values of the percent difference relative to the center peak wavelength; and a ratio of the areas under the curve to all possible values normalized to a minimum-maximum range of 0 to 1, where the ratio is normalized based on a minimum reference of 0.6. In certain embodiments, the FOM is in a range from 0.8 to 0.96. In certain embodiments, the support structure comprises a lead frame at least partially encased in a housing.

In another aspect, an LED package comprises: a support structure forming a recess; a lens over the recess, the lens comprising a lens base that extends from the support structure and a lens upper portion that forms a curved surface above the lens base; and a plurality of LED chips within the recess, wherein a far field pattern of aggregate emissions from the plurality of LED chips has a full width half maximum of less than 60. In certain embodiments, the lens base forms a circular cross-section. In certain embodiments, the lens base forms a rectellipse cross-section. The LED package may further comprise a first cladding layer on a surface of the lens along the lens base. In certain embodiments, the first cladding layer comprises a light-reflective material. In certain embodiments, the first cladding layer comprises a light-absorbing material. The LED package may further comprise a second cladding layer on a surface of the lens along the lens upper portion. In certain embodiments, the plurality of LED chips comprises at least three LED chips configured to generate a plurality of peak wavelengths; and a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of: raw far field pattern data for each LED chip; a noise corrected luminous intensity data of the raw far field pattern data for each LED chip; a percent difference relative to the center peak wavelength for all nonzero noise corrected luminous intensity data; areas under a curve for all absolute values of the percent difference relative to the center peak wavelength; and a ratio of the areas under the curve to all possible values normalized to a minimum-maximum range of 0 to 1, where the ratio is normalized based on a minimum reference of 0.6. In certain embodiments, the FOM is in a range from 0.8 to 0.96. In certain embodiments, the full width half maximum is 30 or less. In certain embodiments, the support structure comprises a lead frame at least partially encased in a housing.

In another aspect, an LED display comprises: a display panel; and at least one LED package comprising: a support structure forming a recess; a lens over the recess, the lens comprising a lens base that extends from the support structure and a lens upper portion that forms a curved surface above the lens base; and a plurality of LED chips within the recess, wherein a far field pattern of aggregate emissions from the plurality of LED chips has a full width half maximum of less than 60. In certain embodiments, the full width half maximum is 40 or less. The LED display may further comprise a cladding layer on a surface of the lens along the lens base, the cladding layer comprising a light-reflective material or a light-absorbing material. In certain embodiments, the plurality of LED chips comprises at least three LED chips configured to generate a plurality of peak wavelengths; and a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of: raw far field pattern data for each LED chip; a noise corrected luminous intensity data of the raw far field pattern data for each LED chip; a percent difference relative to the center peak wavelength for all nonzero noise corrected luminous intensity data; areas under a curve for all absolute values of the percent difference relative to the center peak wavelength; and a ratio of the areas under the curve to all possible values normalized to a minimum-maximum range of 0 to 1, where the ratio is normalized based on a minimum reference of 0.6. In certain embodiments, the FOM is in a range from 0.8 to 0.96. In certain embodiments, the support structure comprises a lead frame at least partially encased in a housing.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package that includes a lead frame structure according to principles of the present disclosure.

FIG. 1B is a cross-sectional view of the LED package of FIG. 1A taken along the sectional line 1B-1B of FIG. 1A.

FIG. 2 is a top view of the LED package of FIG. 1A illustrating a linear arrangement of the LED chips within the recess of the LED package.

FIG. 3 is a top view of the LED package of FIG. 2 illustrating a triangular arrangement of the LED chips within the recess of the LED package.

FIG. 4 is a cross-sectional view of the LED chip of FIG. 1B with the addition of a lens over the recess and LED chips.

FIG. 5 is a top view of the LED package of FIG. 4 for embodiments with a circular or round lens.

FIG. 6 is a top view of an LED package that is similar to the LED package of FIG. 5 except the lens has a circular top and a rounded square base.

FIG. 7 is a top view of an LED package that is similar to the LED package of FIG. 5 except the lens has an oval top.

FIG. 8 is a top view of an LED package that is similar to the LED package of FIG. 6 except the lens has an oval top.

FIG. 9 is a cross-sectional view of an LED package that is similar to the LED package of FIG. 4 with the addition of one or more cladding layers on portions of the lens.

FIG. 10 is a cross-sectional view of an LED package that is similar to the LED package of FIG. 9 with an alternative arrangement of the cladding layers.

FIG. 11 is a cross-sectional view of an LED package that is similar to the LED package of FIG. 9 with another alternative arrangement of the cladding layers.

FIG. 12A is a top perspective view of an LED package where the lens forms a curved top surface above the housing.

FIG. 12B is a top view illustration representing positioning of LED chips within the single recess of the housing of FIG. 12A.

FIG. 12C is a graph of a far field pattern of the LED package of FIGS. 12A and 12B along the V-V direction.

FIG. 12D is a graph of a far field pattern of the LED package of FIGS. 12A and 12B along the H-H direction.

FIG. 13A is a top perspective view of an LED package that is similar to the LED package of FIGS. 12A and 12B but with an alternative arrangement of the LED chips.

FIG. 13B is a top view illustration representing positioning of LED chips within the single recess of the housing of FIG. 13A.

FIG. 13C is a graph of a far field pattern of the LED package of FIGS. 13A and 13B along the V-V direction.

FIG. 13D is a graph of a far field pattern of the LED package of FIGS. 13A and 13B along the H-H direction.

FIG. 14A is a top perspective view of an LED package that is similar to the LED package of FIGS. 13A and 13B but with an alternative height of the lens.

FIG. 14B is a top view illustration representing positioning of LED chips within the single recess of the housing of FIG. 14A.

FIG. 14C is a graph of a far field pattern of the LED package of FIGS. 14A and 14B along the V-V direction.

FIG. 14D is a graph of a far field pattern of the LED package of FIGS. 14A and 14B along the H-H direction.

FIG. 15A is a top perspective view of an LED package that is similar to the LED package of FIGS. 14A and 14B but with the cladding layer positioned along the lens base.

FIG. 15B is a top view illustration representing positioning of LED chips within the single recess of the housing of FIG. 15A.

FIG. 15C is a graph of a far field pattern of the LED package of FIGS. 15A and 15B along the V-V direction.

FIG. 15D is a graph of a far field pattern of the LED package of FIGS. 15A and 15B along the H-H direction.

FIG. 16A is a top perspective view of an LED package that is similar to the LED package of FIGS. 14A and 14B but with a different cross-sectional shape of the lens.

FIG. 16B is a top view illustration representing positioning of LED chips within the single recess of the housing of FIG. 16A.

FIG. 16C is a graph of a far field pattern of the LED package of FIGS. 16A and 16B along the V-V direction.

FIG. 16D is a graph of a far field pattern of the LED package of FIGS. 16A and 16B along the H-H direction.

FIG. 17A is a top perspective view of an LED package that is similar to the LED package of FIGS. 16A and 16B but with the cladding layer positioned along the lens base.

FIG. 17B is a top view illustration representing positioning of LED chips within the single recess of the housing of FIG. 17A.

FIG. 17C is a graph of a far field pattern of the LED package of FIGS. 17A and 17B along the V-V direction.

FIG. 17D is a graph of a far field pattern of the LED package of FIGS. 17A and 17B along the H-H direction.

FIG. 18A is a graph of an exemplary far field pattern of FIG. 14C in the V-V direction and further illustrating the reference total envelope full width half maximum (TEFWHM_{Ref}) relative to the overall emissions from the LED chips.

FIG. 18B is a graph of an exemplary far field pattern of FIG. 14D in the H-H direction and further illustrating the TEFWHM_{Ref} relative to the overall emissions from the LED chips.

FIG. 19A is a graph of the V-V direction far field pattern of FIG. 13C in raw data format.

FIG. 19B is a graph of the H-H direction far field pattern of FIG. 13D in raw data format.

FIG. 19C is a graph with the data from FIG. 19A with noise corrected far field pattern (NC FFP) in the V-V direction.

FIG. 19D is a graph with the data from FIG. 19C with noise corrected far field pattern (NC FFP) in the H-H direction.

FIG. 19E is a graph illustrating the delta from center by normalized TEFWHM values for the plot lines of FIG. 19C in the V-V direction.

FIG. 19F is a graph illustrating the delta from center by normalized TEFWHM, or IvNC % (θ) by TEFWHM values for the plot lines of FIG. 19D in the H-H direction.

FIG. 19G is a graph illustrating absolute values for the plot lines of FIG. 19E.

FIG. 19H is a graph illustrating absolute values for the plot lines of FIG. 19F.

FIG. 20 is a summary table illustrating a figure of merit (FOM) that defines a red-green-blue color quality index metric for various LED package configurations.

FIG. 21 is a schematic diagram of a portion of an LED display screen.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages and more particularly to light mixing arrangements in LED packages. LED packages include multiple LED chips arranged within a single recess or cavity and a single corresponding lens. Light mixing arrangements include LED chip layouts, lens structures, and/or cladding layers for lens structures. LED packages are disclosed with reduced full width half maximum values and improved uniformity in far field pattern emissions by reducing lensing effects of multiple LED chips in a single cavity. A figure of merit is described that defines a color quality index metric, such as a red-green-blue (RGB) color quality index in certain embodiments, that characterizes color quality and uniformity of far field emissions in multiple-color and multiple-chip LED packages.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds.

The active LED structure may be grown on a growth substrate that can include many materials, such as sapphire, silicon, aluminum nitride (AlN), and GaN. Sapphire is a common substrate for Group III nitrides and also has certain advantages, including being lower cost, having established manufacturing processes, and having good light-transmissive optical properties, among other related substrates.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. As used herein, lumiphors and/or lumiphoric materials may include phosphors and/or quantum dots, among others. In certain embodiments, lumiphoric particles may be suspended within a host binder to form a lumiphoric layer. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

In certain embodiments, aspects of the present disclosure relate to LED packages where support structures embody lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

As described above, an exemplary LED package may include multiple LED chips arranged within a common recess and with a common lens of an LED package. Conventional multiple color LED packages have been developed where each individual LED chip is positioned within its own recess relative to its own lens. Challenges exist in combining multiple LED chips of different emission wavelengths in a single recess and under a single lens. Relative positions of LED chips to each other and the focal point of the lens may create unsuitable variations in far field patterns at various viewing angles. According to aspects of the present disclosure, arrangements of LED chips, encapsulants, lenses and/or cladding layers for lenses are disclosed for a common recess that provide improved light mixing in far field patterns. For multiple emission color embodiments, such as red, green, and blue LED chips, such arrangements are provided that effectively mix multiple emission point sources from the multiple LED chips to approximate a single point source from the LED package.

By way of example, the following LED package examples are described in the context of lead frame structures. The principles described are also applicable to LED packages with support structures that embody submount structures. Accordingly, the submount structures may include a ceramic submount or a PCB with a recess for multiple LED chips being formed therein or with laminate structures that build up from mounting surfaces of LED chips.

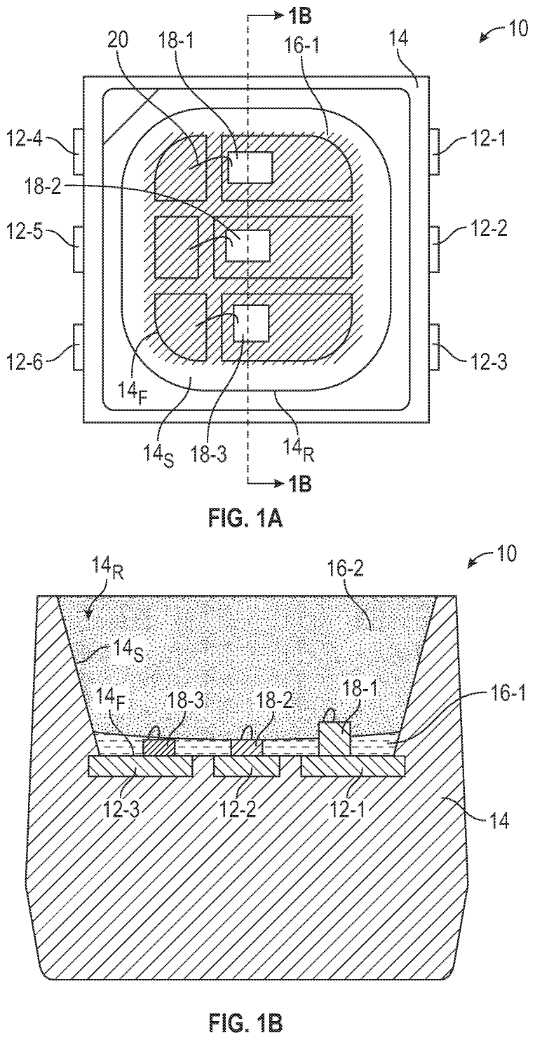

FIG. 1A is a top view of an LED package 10 that includes a lead frame structure collectively formed by a plurality of leads 12-1 to 12-6, a body or housing 14 that encases a portion of the lead frame structure, and a first encapsulation layer 16-1 that is arranged within a recess 14_{R} that is formed by the housing 14. FIG. 1B is a cross-sectional view of the LED package 10 of FIG. 1A taken along the sectional line 1B-1B of FIG. 1A. The LED package 10 includes LED chips 18-1 to 18-3 that are mounted on and electrically coupled respectively to the leads 12-1 to 12-3 and electrically coupled to corresponding leads 12-4 to 12-6 by way of wire bonds 20. While a single wire bond 20 is illustrated for each LED chip 18-1 to 18-3, it is understood that various ones of the LED chips 18-1 to 18-3 may embody a lateral structure where a second wire bond may be employed to provide electrical coupling.

In certain aspects, each of the LED chips 18-1 to 18-3 may be configured to emit a different wavelength from the other LED chips. For example, the LED chip 18-1 may be configured to emit red light, the LED chip 18-2 may be configured to emit green light, and the LED chip 18-3 may be configured to emit blue light. While three LED chips 18-1 to 18-3 are illustrated, the principles disclosed herein are applicable to any number of LED chips within the LED package 10. The recess 14_{R} may include a recess floor 14_{F} and one or more recess sidewalls 14_{S}. The leads 12-1 to 12-6 may be arranged to extend through the housing 14 and a portion of the leads 12-1 to 12-6 may be arranged along or otherwise exposed at the recess floor 14_{F}.

As best illustrated in FIG. 1B, the first encapsulation layer 16-1 may be arranged on portions of the one or more recess sidewalls 14_{S}, along the recess floor 14_{F}, and covering portions of the leads 12-1 to 12-6 that are arranged along the recess floor 14_{F}. Depending on various geometries of the LED chips 18-1 to 18-3, the first encapsulation layer 16-1 may cover one or more sidewalls of the LED chips 18-1 to 18-3, as well as some top surfaces of the LED chips 18-1 to 18-3. For example, one or more portions of the LED chip 18-1 may extend above top surfaces of the first encapsulation layer 16-1. The first encapsulation layer 16-1 may include an epoxy or silicone, depending on the application. A second encapsulation layer 16-2, which may also include silicone or epoxy, may fill the remainder of the recess 14_{R} above the first encapsulation layer 16-1. In certain aspects, both the first encapsulation layer 16-1 and the second encapsulation layer 16-2 may comprise a same material with same optical properties. For example, both encapsulation layers 16-1, 16-2 may include epoxy. In further embodiments, both encapsulation layers 16-1, 16-2 may be configured to be light-transmissive and/or light-transparent to wavelengths of light generated by the LED chips 18-1 to 18-3. In the example where the LED chip 18-1 extends above the first encapsulation layer 16-1, one or more portions of the LED chip 18-1, such as a top surface of the LED chip 18-1 may extend into or otherwise reside within the second encapsulation layer 16-2.

The first encapsulation layer 16-1 may be dispensed within the recess 14_{R} and around one or more of the LED chips 18-1 to 18-3. In certain embodiments, the first encapsulation layer 16-1 may be allowed to settle within the recess 14_{R} for a time period at an elevated temperature, but below a curing temperature for the first encapsulation layer 16-1. After settling, the first encapsulation layer 16-1 may be subjected to a first curing step. The first curing step may involve a full cure or a partial cure of the first encapsulation layer 16-1. Parameters for the first curing step for the first encapsulation layer 16-1 may be varied based on a desired arrangement for stress mitigation. Such parameters may include lower curing temperatures, slowing temperature ramping during curing, shorter curing times at hotter temperatures, and longer curing times at lower temperatures. The second encapsulation layer 16-2 may then be formed over the first encapsulation layer 16-1 and a second curing step may be performed to cure the second encapsulation layer 16-2. In certain embodiments, portions of the first encapsulation layer 16-1 that were not fully cured in the first curing step may be cured by the second curing step. In this regard, encapsulation for the LED package 10 may be provided by a multiple-step process. The presence of the first encapsulation layer 16-1 that covers the recess floor 14_{F} and portions of the LED chips 18-1 to 18-3 effectively forms a buffer for stress that may be present in the second encapsulation layer 16-2 due to curing shrinkage and/or operating conditions of the LED package 10. In this manner, the stress profile of the LED package 10 may be redistributed such that delamination of the LED chips 18-1 to 18-3 is avoided.

As disclosed herein, arrangements of LED chips within a single recess and a corresponding lens over the recess are described that provide improved color mixing in far field patterns, particularly for narrow emission applications. Lenses as described herein are provided relative to multiple LED chips in a single recess to provide more narrow aggregate emissions from LED packages. Similar LED packages without shaped lenses, such as flat top encapsulants, typically have broader emissions such as a full width half maximum (FWHM) of about 115°. For applications where a narrower FWHM is desired, shaped lenses such as domed or bullet shaped with curved top surfaces are provided that redirect broader emissions and achieve FWHM values of less than 60°, or 50° or below, or 40° or below, or 30° or below, or 20° or below. However, lenses for conventional LED packages may not provide suitable color mixing for multiple chips. For example, when multiple LED chips are positioned beneath a single lens, each of the LED chips are positioned differently relative to an optical axis or focal point of the lens. Accordingly, individual emissions peaks may be offset from one another in aggregate emissions, thereby creating off peak artifacts, undesirable color mixing and reduced color uniformity by viewing angle.

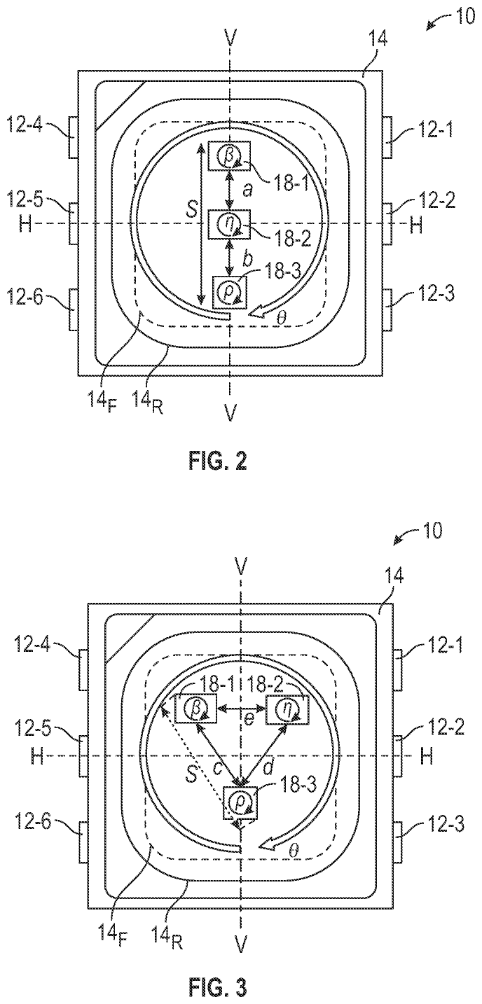

According to aspects of the present disclosure, arrangements for LED chips may be defined by various parameters, including spacings between LED chips, linear or nonlinear (e.g., triangular for three LED chips) LED chip arrangements, rotations of overall LED chip arrangements, and/or rotations of individual LED chips. According to further aspects of the present disclosure, structures for lenses and/or associated cladding layers may be defined by parameters such as various lens dimensions including lens heights, lens base dimensions, and/or wall shapes. For cladding layers relative to lenses, parameters may include locations and dimensions of one or more cladding layers relative to lenses. Various combinations of LED chip arrangements relative to lens structures and cladding layers are described that provide improved color mixing in far field patterns for applications with FWHM values of 30° or below or 20° or below. FIGS. 2 to 12 are provided to illustrate various parameters for multiple-chip LED packages according to principles of the present disclosure.

FIG. 2 is a top view of the LED package 10 of FIG. 1A illustrating a linear arrangement of the LED chips 18-1 to 18-3 within the recess 14_{R} of the LED package 10. Superimposed vertical line V-V represents a vertical axis of the LED package 10 and horizontal line H-H represents a horizontal axis of the LED package 10. As illustrated, the LED chip 18-2 is positioned at a center point of the recess 14_{R}. The spacing or distance between the LED chip 18-1 and the LED 18-2 is labeled as distance a, and the distance between the LED chip 18-3 and the LED 18-2 is labeled as distance b. When the distances a and b have a zero value, the LED chips 18-1 to 18-3 are positioned in a linear manner with no spaces therebetween. An overall spacing S defines a distance of the longest dimension, or widest separation, of the arrangement of LED chips 18-1 to 18-3, in this case a distance from an outer edge of the LED chip 18-1 to an outer edge of the LED chip 18-3. As further illustrated in FIG. 2, a rotation of the linear arrangement of LED chips 18-1 to 18-3 along a plane parallel to the recess floor 14_{F} is labeled as rotation angle θ, a rotation of each individual LED chip 18-1 to 18-3 relative to the plane parallel to the recess floor 14_{F} is labeled respectively as rotation angles β, η, and ρ. Any of the rotation angles for θ, β, η, and ρ could be in a range from 0° to 360° where the rotations illustrated in FIG. 2 are at rotation angles of 0° relative to the horizontal axis H-H. The emission colors of the LED chips 18-1 to 18-3 may be any combination of red, green, and blue emission colors in certain embodiments.

FIG. 3 is a top view of the LED package 10 of FIG. 2 illustrating a triangular arrangement of the LED chips 18-1 to 18-3 within the recess 14_{R} of the LED package 10. As illustrated, the LED chips 18-1 to 18-3 may be positioned in the triangular arrangement relative to the center point of the LED package 10. The distance between the LED chip 18-1 and the LED 18-3 is labeled as distance c, the distance between the LED chip 18-2 and the LED 18-3 is labeled as distance d, and the distance between the LED chip 18-1 and the LED 18-2 is labeled as distance e. When the distances c, d and e have a zero value, the LED chips 18-1 to 18-3 are positioned in a triangular manner with no spaces therebetween. The overall spacing S that defines the distance of the longest dimension, or widest separation, for the triangular arrangement corresponds to a longest distance from an outer corner of the farthest two of the LED chips 18-1 to 18-3, in this case the distance between outer corners of the LED chip 18-3 and either of the LED chips 18-1 or 18-2. The emission colors of the LED chips 18-1 to 18-3 may be any combination of red, green, and blue emission colors in certain embodiments. As with FIG. 2, the principles of the present disclosure are applicable to arrangements where the rotation angles for θ, β, η, and ρ could be in a range from 0° to 360°.

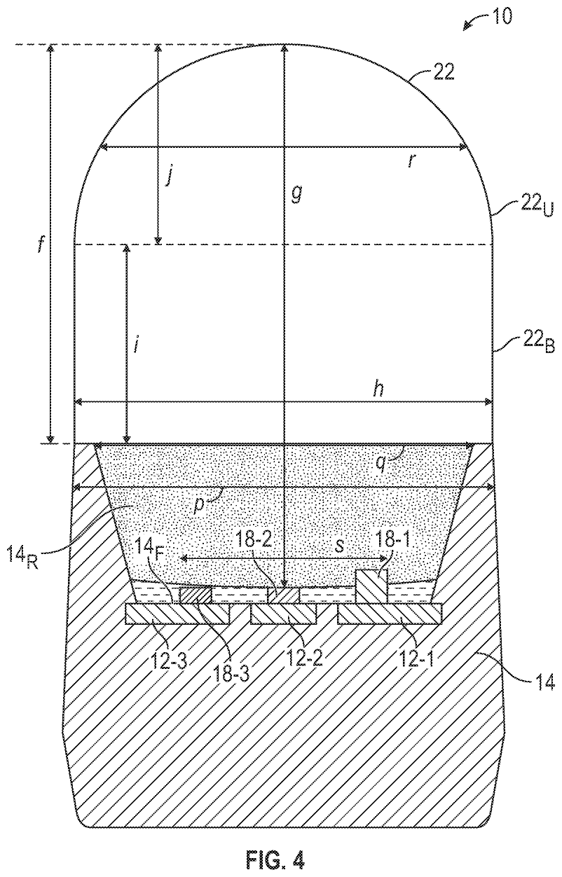

FIG. 4 is a cross-sectional view of the LED package 10 of FIG. 1B with the addition of a lens 22 over the recess 14_{R} and LED chips 18-1 to 18-3. As illustrated, the lens 22 may include a lens base 22_{B} that extends up from the housing 14 and a lens upper portion 22_{U}. For illustrative purposes, a superimposed horizontal dashed line is provided to delineate the lens base 22_{B} from the lens upper portion 22_{U}. An overall height f is defined as a height of the lens 22 from a topmost surface of the housing 14 to a topmost surface of the lens 22. The overall height f is subdivided where height i defines a height of the lens base 22_{B}, and height j defines a height from the lens base 22_{B} to the topmost surface of the lens 22. A height g defines a height from the topmost surface of the lens 22 to a top surface of a light-emitting surface defined by the LED chips 18-1 to 18-3 at a center of the LED package 10. Distance h defines a lens base dimension, and distance r defines a dimension of the lens upper portion 22_{U} corresponding to a curved upper surface of the lens 22. As illustrated, the distance r defines a cross-section of the lens 22 at a curved half height (i.e., j/2) of the lens upper portion 22_{U}. In relation to the housing 14, distance p defines a dimension of the top exterior surface of the housing 14 and distance q defines a dimension of the opening of the recess 14_{R}.

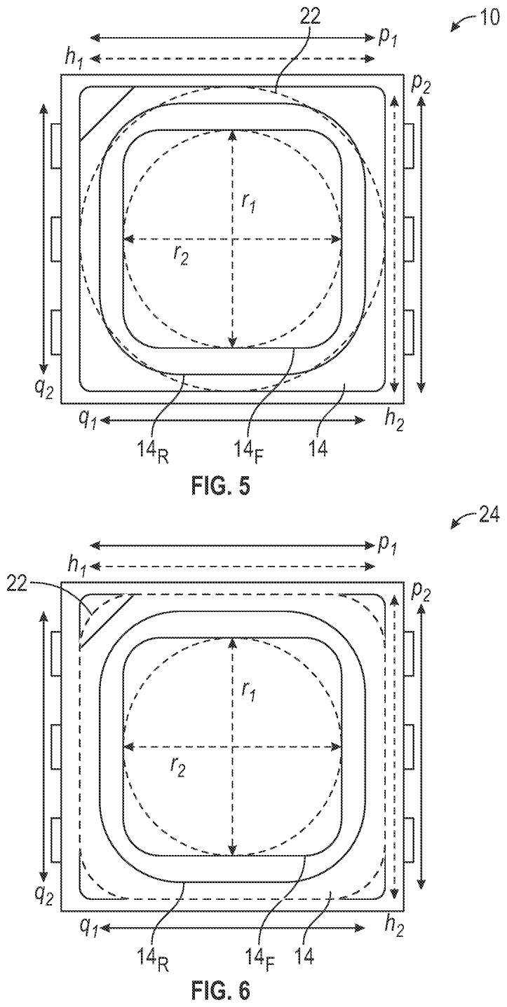

FIG. 5 is a top view of the LED package 10 of FIG. 4 for embodiments with a circular or round lens 22. For a circular top of the lens 22, the distances r₁ and r₂ define same distances (i.e., r₁=r₂) for cross-sections of the lens 22 at the curved half height (i.e., j/2) of FIG. 4. For a circular base section of the lens, distances h₁ and h₂ define same distances (i.e., h₁=h₂) for cross-sections of the lens 22 at the lens base 22_{B} of FIG. 4. From the top view, distances p₁ and p₂ define dimensions of the top exterior surface of the housing 14, and distances q₁ and q₂ define dimensions of the opening of the recess 14_{R}. In certain embodiments, the curved base of the lens 22 at distances h₁ and h₂ may be the same or similar to the distances p₁ and p₂ of the housing 14.

FIG. 6 is a top view of an LED package 24 that is similar to the LED package 10 of FIG. 5 except the lens 22 has a circular top and a rounded square base. In this regard, the distances r₁ and r₂ are the same (i.e., r₁=r₂) for the circular upper portion of the lens 22, and the distances h₁ and h₂ for the base of the lens 22 may be the same or similar to the distances p₁ and p₂ of the housing 14. However, the base of the lens 22 has longer portions that are the same as the housing 14 (i.e., h₁=p₁ or h₂=p₂). In this manner, more portions of the lens 22 extend over topmost surfaces of the housing 14 proximate corners thereof. In certain embodiments, the base of the lens 22 may form a rectellipse shape.

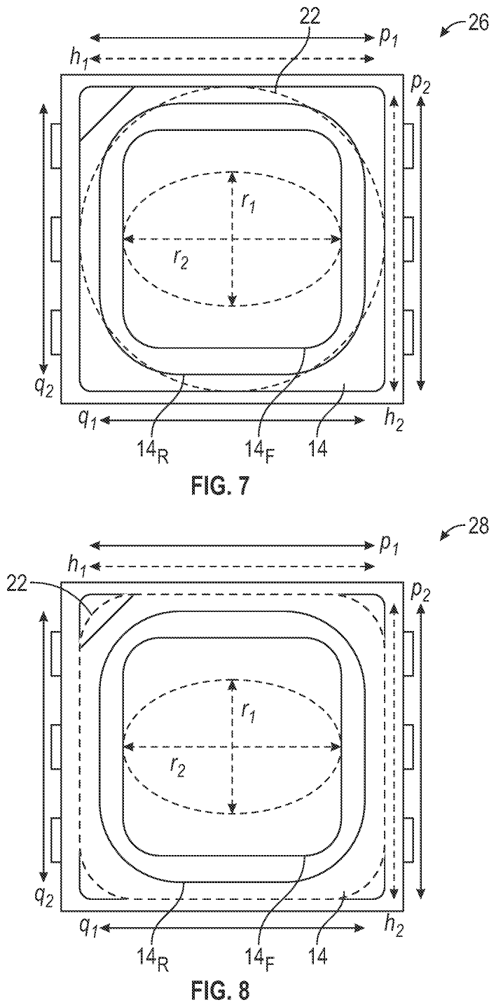

FIG. 7 is a top view of an LED package 26 that is similar to the LED package 10 of FIG. 5 except the lens 22 has an oval top. In this manner, the distances r₁ and r₂ define different distances (i.e., r₁≠r₂) for cross-sections of the lens 22 at the curved half height (i.e., j/2) of FIG. 4.

FIG. 8 is a top view of an LED package 28 that is similar to the LED package 24 of FIG. 6 except the lens 22 has an oval top. In this manner, the distances r₁ and r₂ define different distances (i.e., r₁≠r₂) for cross-sections of the lens 22 at the curved half height (i.e., j/2) of FIG. 6.

In certain embodiments, one or more cladding layers may be added along one or more lens portions to provide improved light mixing. A cladding layer may be positioned at one or more of a lens base and/or an upper portion of the lens to effectively redirect, reflect, or absorb light for color mixing purposes. The cladding layer may form a coating along one or more exterior surfaces of the lens. In certain embodiments, the cladding layer comprise a light-reflective and/or light-refracting material. In certain embodiments, the cladding layer may have a white color for light-reflecting purposes. In other embodiments, the cladding layer may comprise a light-absorbing material with a dark and/or black color. Exemplary materials for light-reflective and/or light-refracting cladding layers may include one or more of polyphthalamide (PPA), titanium dioxide (TiO₂), silicon dioxide (SiO₂), aluminum (AI), silver (Ag), gold (Au), platinum (Pt), palladium (Pd), or similar materials or combinations thereof. Exemplary material for a light-absorbing cladding layer may include carbon black, iron black, or similar materials. A cladding layer may be positioned at a base of the lens, providing coverage from a topmost surface of the housing. In other embodiments, a cladding layer may be positioned in a spaced apart relationship from a topmost surface of the housing.

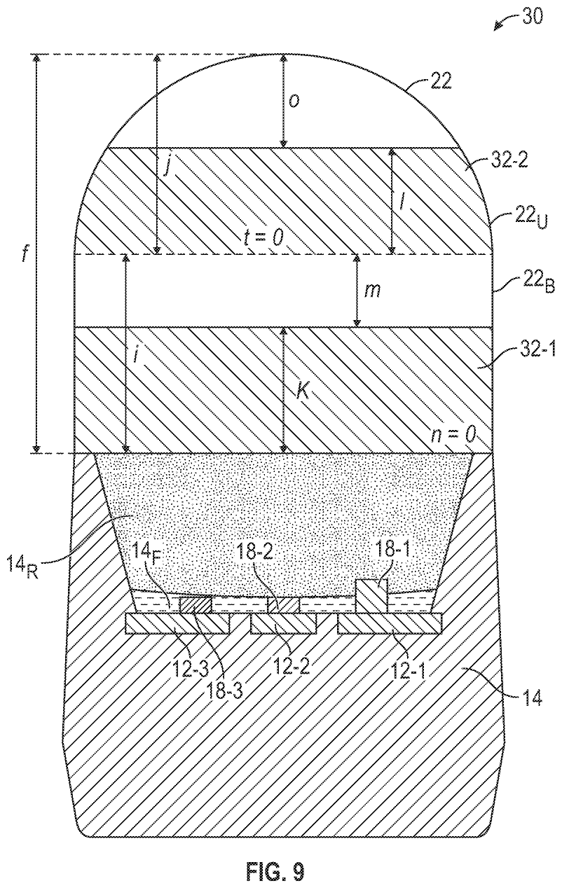

FIG. 9 is a cross-sectional view of an LED package 30 that is similar to the LED package 10 of FIG. 4 with the addition of one or more cladding layers 32-1, 32-2 on portions of the lens 22. In certain embodiments, one cladding layer 32-1 may be positioned at the lens base 22_{B} directly adjacent the topmost surface of the housing 14. A height k is defined as a height of the cladding layer 32-1 along the lens base 22_{B} from a topmost surface of the housing 14. A height m is defined as a distance from a top of the cladding layer 32-1 to a top of the lens base 22_{B}. A height n is defined as a gap between the bottom of the cladding layer 32-1 and the topmost surface of the housing 14. In FIG. 9, n=0 since the cladding layer 32-1 begins at topmost surface of the housing 14 so that no such gap exists. In certain embodiments, another cladding layer 32-2 may be positioned along the lens upper portion 22_{U} where the lens 22 has curved surfaces. A height l is defined as a height of the cladding layer 32-2 along the lens upper portion 22_{U} and from the lens base 22_{B}. A height o is defined as a distance from a top of the cladding layer 32-2 to a topmost surface of the lens 22. A height t is defined as a gap between the bottom of the lens upper portion 22_{U} and where the cladding layer 32-2 begins. In FIG. 9, t=0 since the cladding layer 32-2 begins at the bottom of the lens upper portion 22_{U} so that no such gap exists.

As illustrated in FIG. 9, the cladding layer 32-1 may redirect and/or reflect laterally propagating light along the lens base 22_{B} to provide more uniform far field patterns from the LED chips 18-1 to 18-3. In a similar manner, the cladding layer 32-2 may be further redirect and/or reflect laterally propagating light along the lens upper portion 22_{U} of the lens 22 for similar purposes. In certain embodiments, the LED package 30 may only have one of the cladding layers 32-1 or 32-2.

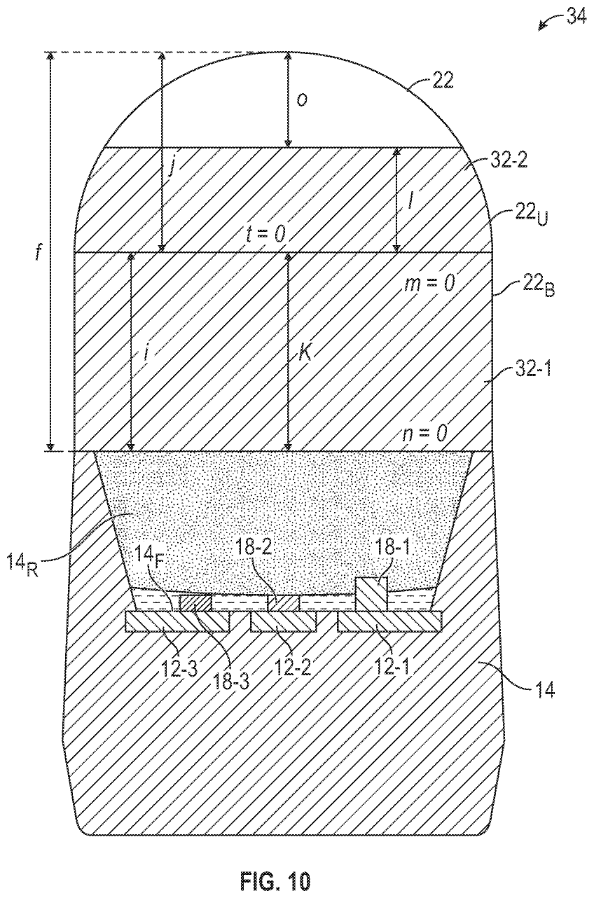

FIG. 10 is a cross-sectional view of an LED package 34 that is similar to the LED package 30 of FIG. 9 with an alternative arrangement of the cladding layers 32-1, 32-2. In FIG. 10, no gap exists between the cladding layers 32-1, 32-2 such that the height m, defined as the distance from the top of the cladding layer 32-1 to the top of the lens base 22_{B}, is zero (i.e., m=0). Accordingly, the cladding layers 32-1, 32-2 essentially form a single cladding layer that extends from the lens base 22_{B} into the lens upper portion 22_{U} of the lens 22.

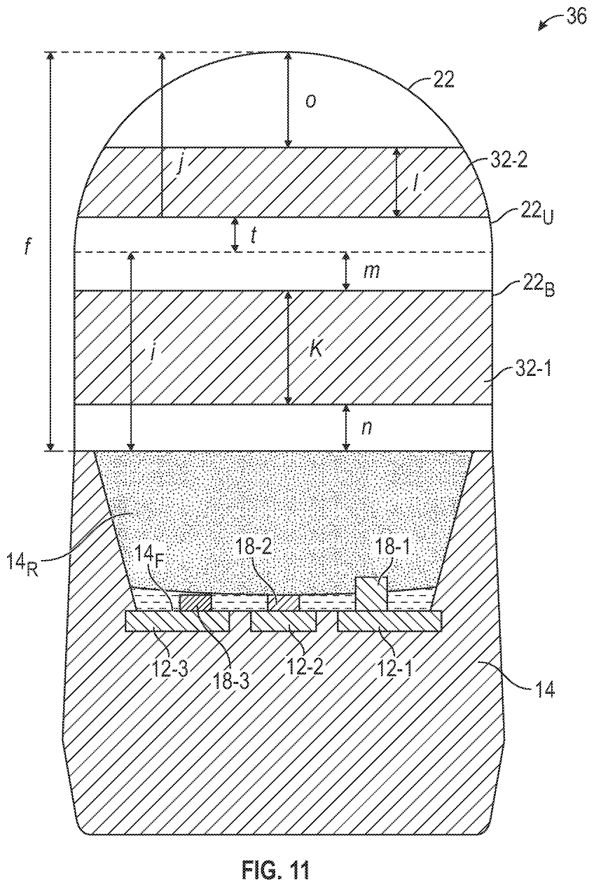

FIG. 11 is a cross-sectional view of an LED package 36 that is similar to the LED package 30 of FIG. 9 with another alternative arrangement of the cladding layers 32-1, 32-2. In FIG. 11, a gap exists between the bottom of the lens upper portion 22_{U} and where the cladding layer 32-2 begins. Accordingly, t≠0 since the cladding layer 32-2 begins at a position spaced from the bottom of the lens upper portion 22_{U}.

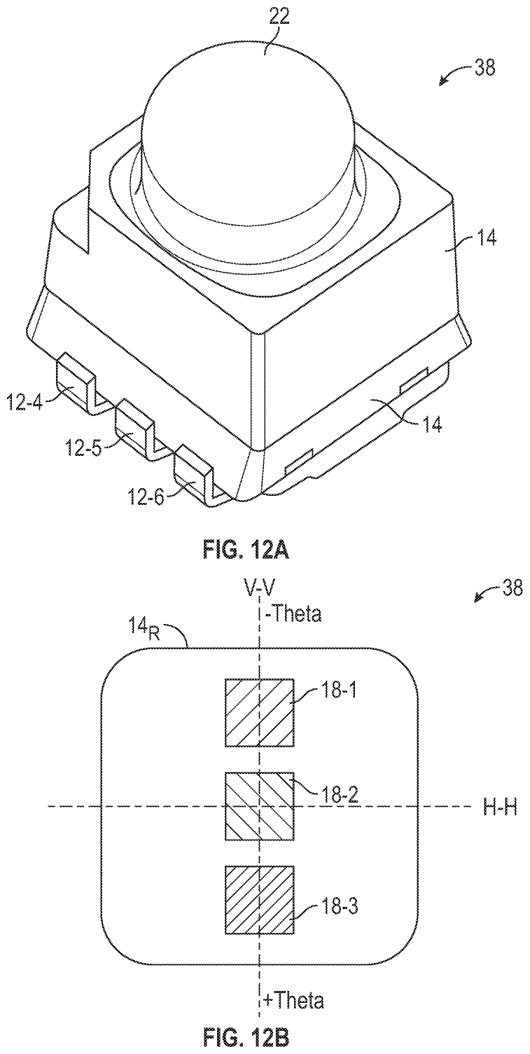

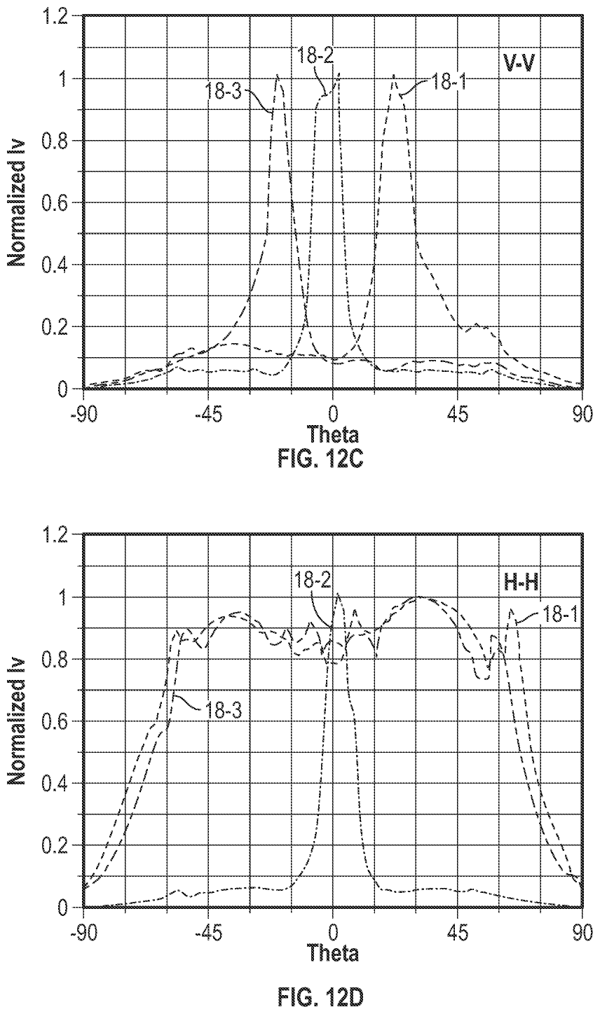

FIG. 12A is a top perspective view of an LED package 38 where the lens 22 forms a curved top surface above the housing 14. In this example, the overall height (i.e., height f of FIG. 4) of the lens 22 is set at 1.5 millimeters (mm) and the lens 22 is formed with a generally round or circular cross-sectional shape all the way to a top of the housing 14. FIG. 12B is a top view illustration representing positioning of LED chips 18-1 to 18-3 within the single recess 14_{R} of the housing 14 of FIG. 12A. As illustrated, the LED chips 18-1 to 18-3 are aligned in a linear manner with the LED chip 18-2 being positioned at a center point of the recess 14_{R}. The relative spacing between the LED chips 18-1, 18-3 relative to the LED chip 18-2 (i.e., as distance a and distance b of FIG. 2) are about 325 microns (μm). The linear arrangement is along the vertical direction V-V relative to the horizontal direction H-H. The V-V direction is labeled with relative +/−theta directions indicating angular viewing angles from a center point where the LED chip 18-2 is positioned (i.e., theta=0). Similar relative +/−theta directions are also present for the H-H direction.

FIG. 12C is a graph of a far field pattern of the LED package 38 of FIGS. 12A and 12B along the V-V direction. In FIG. 12C, the y-axis represents a relative light intensity (i.e., normalized luminous intensity Iv) while the x-axis represents theta values along the V-V direction of FIG. 12B. Since the LED chip 18-2 is centrally positioned, the emission peak and FWHM are generally centered at a theta=0 position. Emission peaks for the LED chips 18-1 and 18-3 are positioned with a theta offset from center in a range from 18° to 20°. Additionally, the LED chips 18-1 and 18-3 have wider angle emission variations or impurities.

FIG. 12D is a graph of a far field pattern of the LED package 38 of FIGS. 12A and 12B along the H-H direction. In FIG. 12D, the y-axis represents a relative light intensity (i.e., normalized luminous intensity Iv) while the x-axis represents theta values along the H-H direction of FIG. 12D. Since the LED chip 18-2 is centrally positioned, the emission peak and FWHM are generally centered at a theta=0 position. Emissions for the LED chips 18-1 and 18-3 have higher intensities across wider theta values since the LED chips 18-1 and 18-3 are positioned at a theta=0 value for the H-H direction but offset from theta=0 in the V-V direction.

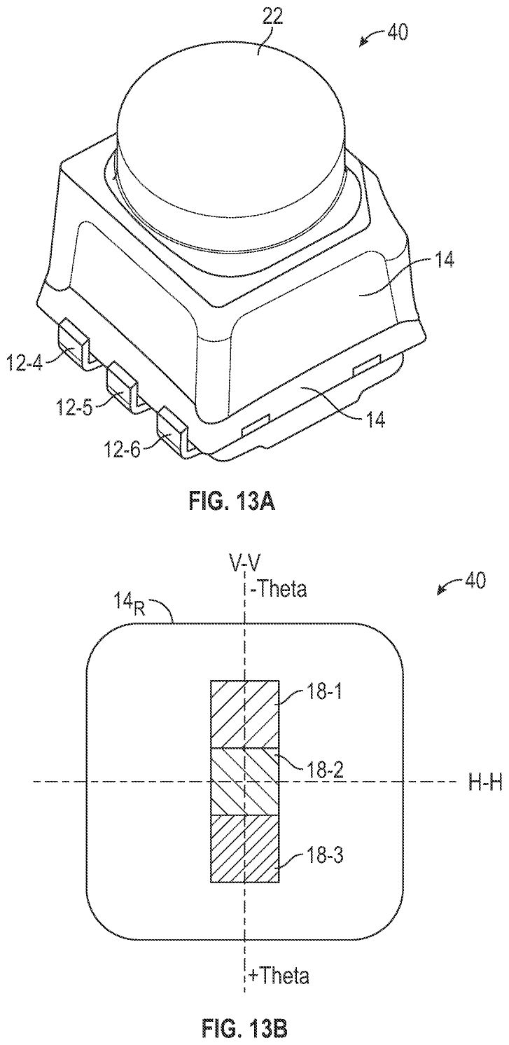

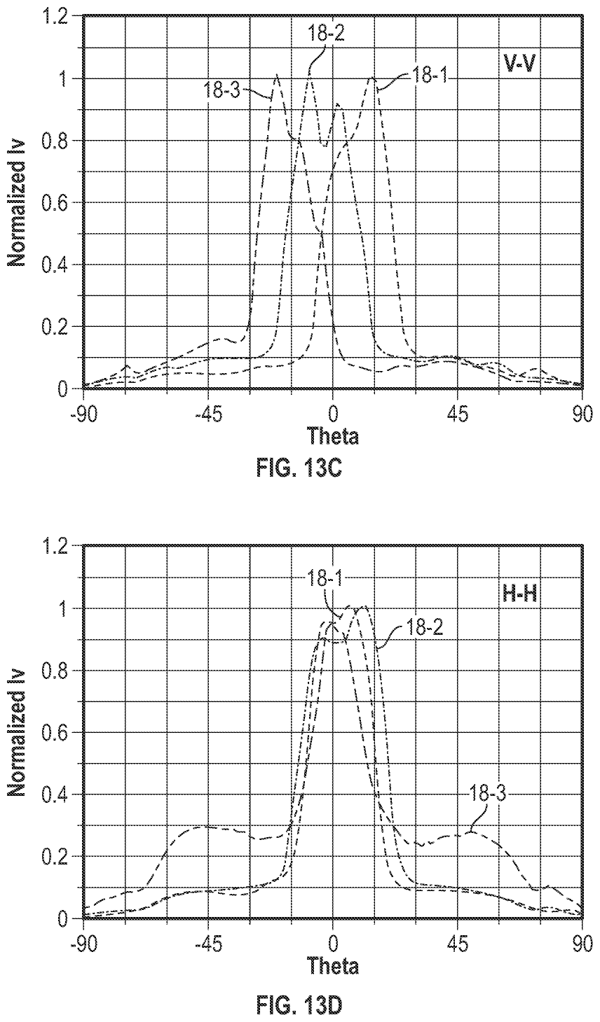

FIG. 13A is a top perspective view of an LED package 40 that is similar to the LED package 38 of FIGS. 12A and 12B but with an alternative arrangement of the LED chips 18-1 to 18-3. FIG. 13B is a top view illustration representing positioning of LED chips 18-1 to 18-3 within the single recess 14_{R} of the housing 14 of FIG. 13A. As illustrated, the LED chips 18-1 to 18-3 are closer together than the LED package 38 of FIGS. 12A and 12B. For example, the relative spacing between the LED chips 18-1, 18-3 relative to the LED chip 18-2 (i.e., as distance a and distance b of FIG. 2) is about 0 μm such that one or more portions of adjacent LED chips 18-1, 18-2, 18-3 are in direct contact with one another.

FIG. 13C is a graph of a far field pattern of the LED package 40 of FIGS. 13A and 13B along the V-V direction. In FIG. 13C, the y-axis represents a relative light intensity (i.e., normalized luminous intensity Iv) while the x-axis represents theta values along the V-V direction of FIG. 13B. Since the LED chip 18-2 is centrally positioned, the emission peak and FWHM are generally centered at a theta=0 position in a similar manner as FIG. 12C. Emission peaks for the LED chips 18-1 and 18-3 are positioned with a theta offset from center in a range from 13° to 15°, which is closer than FIG. 12C due to the closer chip spacings. As illustrated, the LED chips 18-1 and 18-3 also have wider angle emission variations or impurities but these are reduced in comparison with FIG. 12C.

FIG. 13D is a graph of a far field pattern of the LED package 40 of FIGS. 13A and 13B along the H-H direction. In FIG. 13D, the y-axis represents a relative light intensity (i.e., normalized luminous intensity Iv) while the x-axis represents theta values along the H-H direction of FIG. 13D. Since the LED chip 18-2 is centrally positioned, the emission peak and FWHM are generally centered at a theta=0 position. Emissions for the LED chips 18-1 and 18-3 are more closely aligned with the LED chip 18-2, but wider angle emission variations or impurities are still present.

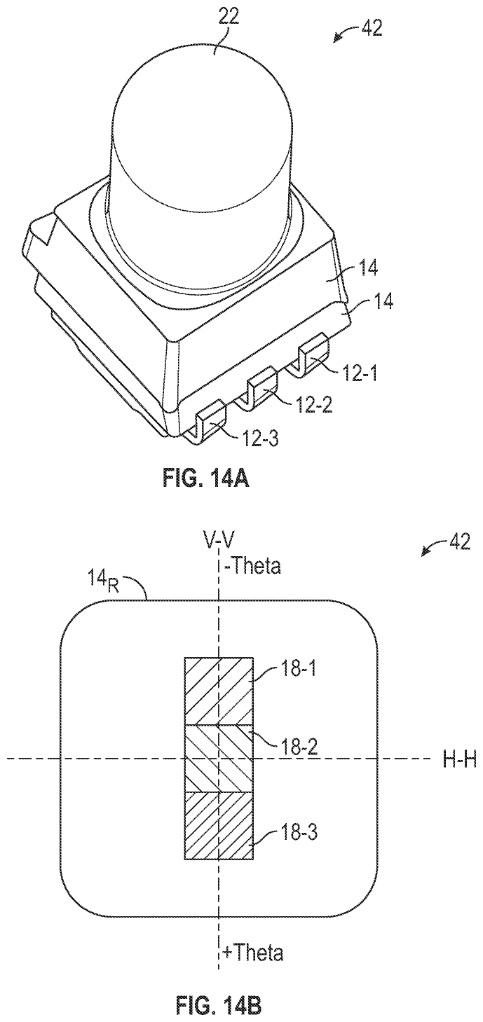

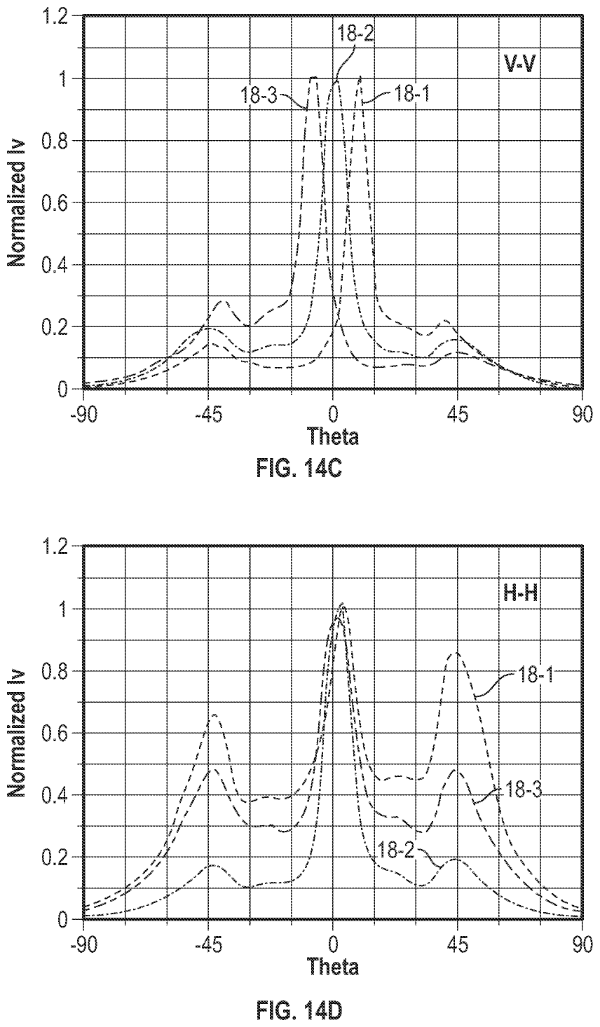

FIG. 14A is a top perspective view of an LED package 42 that is similar to the LED package 40 of FIGS. 13A and 13B but with an alternative height of the lens 22. For the LED package 42, the overall height (i.e., height f of FIG. 4) of the lens 22 is increased to a value of 2.4 mm. FIG. 14B is a top view illustration representing positioning of LED chips 18-1 to 18-3 within the single recess 14_{R} of the housing 14 of FIG. 14A. In FIG. 14B, the LED chips 18-1 to 18-3 are positioned with relative spacings (i.e., distance a and distance b of FIG. 2) of about 0 μm such that one or more portions of adjacent LED chips 18-1, 18-2, 18-3 are in direct contact with one another.

FIG. 14C is a graph of a far field pattern of the LED package 42 of FIGS. 14A and 14B along the V-V direction. In FIG. 14C, the y-axis represents a relative light intensity (i.e., normalized luminous intensity Iv) while the x-axis represents theta values along the V-V direction of FIG. 14B. With the increased height of the lens, emission peaks for the LED chips 18-1 and 18-3 are improved relative to FIG. 13C where theta offsets from center are in a range from 6° to 10°. However, the LED chips 18-1 and 18-3 exhibit increased wider angle emission variations or impurities relative to FIG. 13C.

FIG. 14D is a graph of a far field pattern of the LED package 42 of FIGS. 14A and 14B along the H-H direction. In FIG. 14D, the y-axis represents a relative light intensity (i.e., normalized luminous intensity Iv) while the x-axis represents theta values along the H-H direction of FIG. 14D. As illustrated, emissions for the LED chips 18-1 and 18-3 exhibit significant off-peak artifacts in the H-H direction, contributing to increased wide angle emission variations.

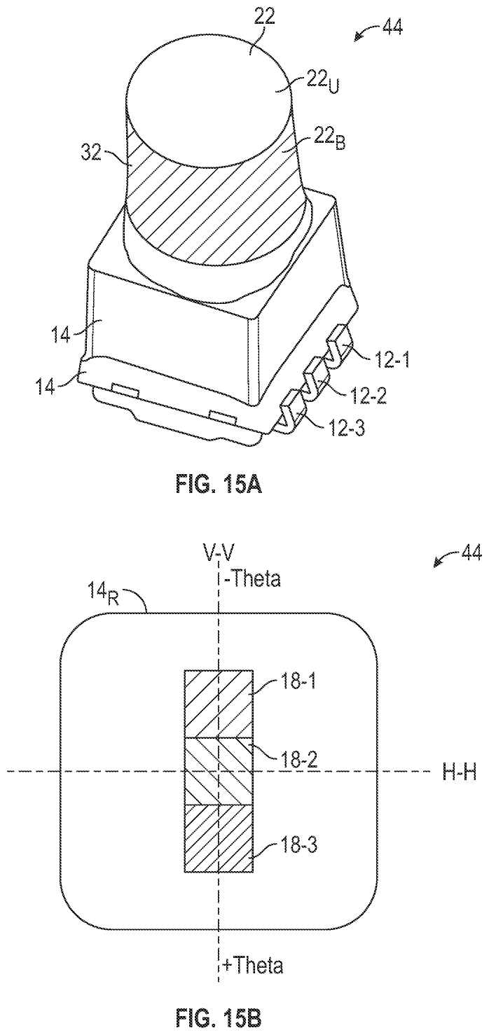

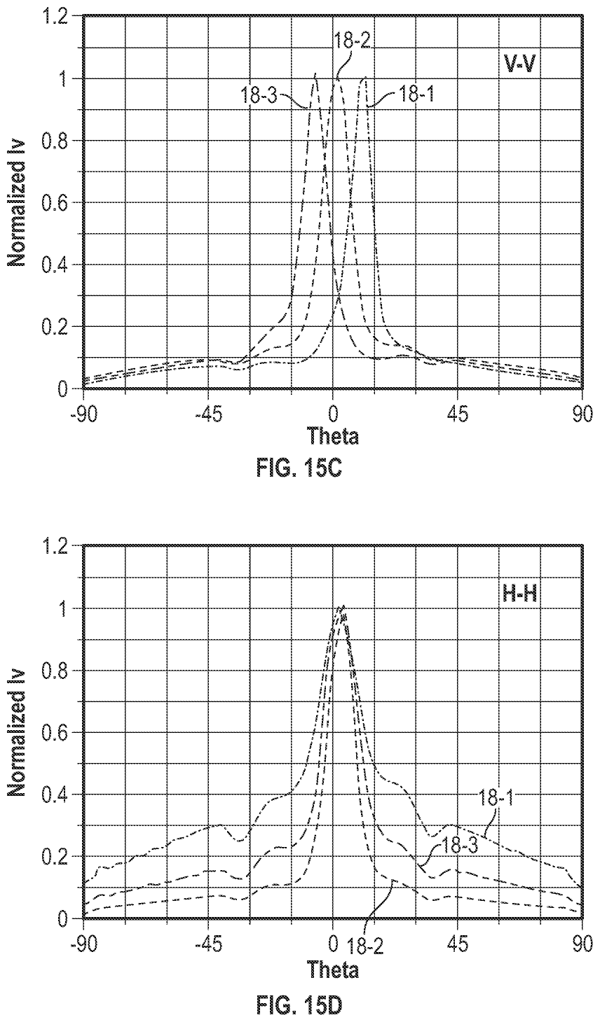

FIG. 15A is a top perspective view of an LED package 44 that is similar to the LED package 42 of FIGS. 14A and 14B but with a cladding layer 32 positioned along the lens base 22_{B}. The cladding layer 32 is arranged on the lens base 22_{B} to extend up from the housing 14 and along sidewalls of the lens 22 up to the lens upper portion 22_{U} of the lens 22. In this regard, the cladding layer 32 may be defined by parameters as illustrated in FIGS. 4 and 9-11 where the cladding layer 32-1 covers the lens base 22_{B} defined by the height i and the height n=0. Specifically, the overall height f of the lens 22 is 2.650 millimeters (mm) and the height of the cladding layer 32 is defined by a value of 1.650 mm for the height i. In this manner, the cladding layer 32 covers the vertical height (e.g., height i) of the lens 22 and does not extend to the domed portion j defined above the lens base 22_{B}. FIG. 15B is a top view illustration representing positioning of LED chips 18-1 to 18-3 within the single recess 14_{R} of the housing 14 of FIG. 15A. In FIG. 15B, the LED chips 18-1 to 18-3 are positioned with relative spacings (i.e., distance a and distance b of FIG. 2) of about 0 μm such that one or more portions of adjacent LED chips 18-1, 18-2, 18-3 are in direct contact with one another.

FIG. 15C is a graph of a far field pattern of the LED package 44 of FIGS. 15A and 15B along the V-V direction. In FIG. 15C, the y-axis represents a relative light intensity (i.e., normalized luminous intensity Iv) while the x-axis represents theta values along the V-V direction of FIG. 15B. With the presence of the cladding layer 32 and the increased height of the lens 22, emission peaks for the LED chips 18-1 and 18-3 are improved where theta offsets from center are in a range from 8° to 10°. Additionally, the LED chips 18-1 and 18-3 exhibited significantly decreased wider angle emission variations or impurities relative to FIG. 14C. Accordingly, the presence of the cladding layer 32 effectively redirects wide angle emission light, such as at or near 45° off-peak or off-center, to escape through the lens upper portion 22_{U} of the lens 22, thereby exhibiting a narrower FWHM (i.e., less than 15° for all LED chips 18-1 to 18-3).

FIG. 15D is a graph of a far field pattern of the LED package 44 of FIGS. 15A and 15B along the H-H direction. In FIG. 15D, the y-axis represents a relative light intensity (i.e., normalized luminous intensity Iv) while the x-axis represents theta values along the H-H direction of FIG. 15D. As illustrated, emissions for the LED chips 18-1 and 18-3 exhibit significant decreased off-peak artifacts in the H-H direction as compared with FIG. 14D. Again, the presence of the cladding layer 32 effectively redirects wide angle emission light.

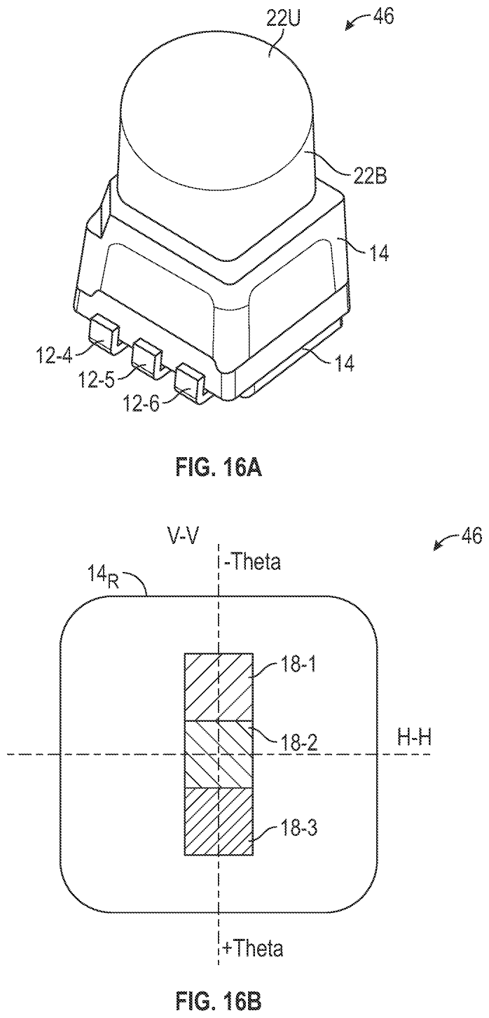

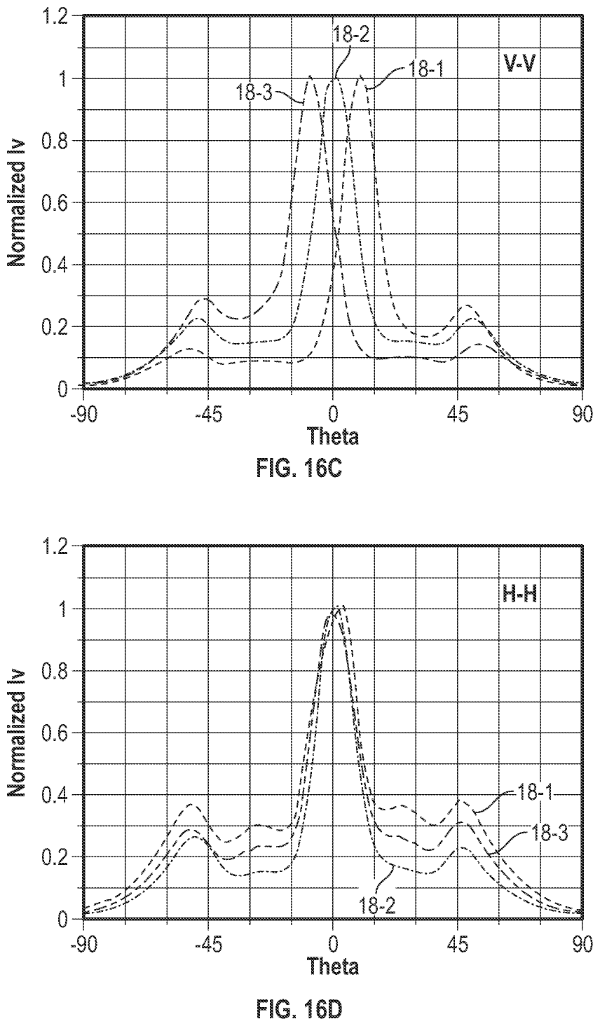

FIG. 16A is a top perspective view of an LED package 46 that is similar to the LED package 42 of FIGS. 14A and 14B but with a different cross-sectional shape of the lens 22. FIG. 16B is a top view illustration representing positioning of LED chips 18-1 to 18-3 within the single recess 14_{R} of the housing 14 of FIG. 16A. In FIG. 16A, the lens 22 is formed with a rectellipse cross-sectional shape that generally follows the outline of the recess 14_{R} of FIG. 16B. In this manner, opposing walls of the lens 22 that extend upward from the housing 14 may be generally planar with rounded corners therebetween.

FIG. 16C is a graph of a far field pattern of the LED package 46 of FIGS. 16A and 16B along the V-V direction. In FIG. 16C, the y-axis represents a relative light intensity (i.e., normalized luminous intensity Iv) while the x-axis represents theta values along the V-V direction of FIG. 16B. With the rectellipse shape for the lens 22, emission peaks for the LED chips 18-1 and 18-3 are similar to FIG. 14C where theta offsets from center are in a range from 6° to 10°. Additionally, the LED chips 18-1 and 18-3 also exhibit increased wider angle emission variations or impurities in a similar manner as FIG. 13C.

FIG. 16D is a graph of a far field pattern of the LED package 46 of FIGS. 16A and 16B along the H-H direction. In FIG. 16D, the y-axis represents a relative light intensity (i.e., normalized luminous intensity Iv) while the x-axis represents theta values along the H-H direction of FIG. 16D. As illustrated, emissions for the LED chips 18-1 and 18-3 exhibit increased off-peak artifacts in the H-H direction in a similar manner as FIG. 14D.

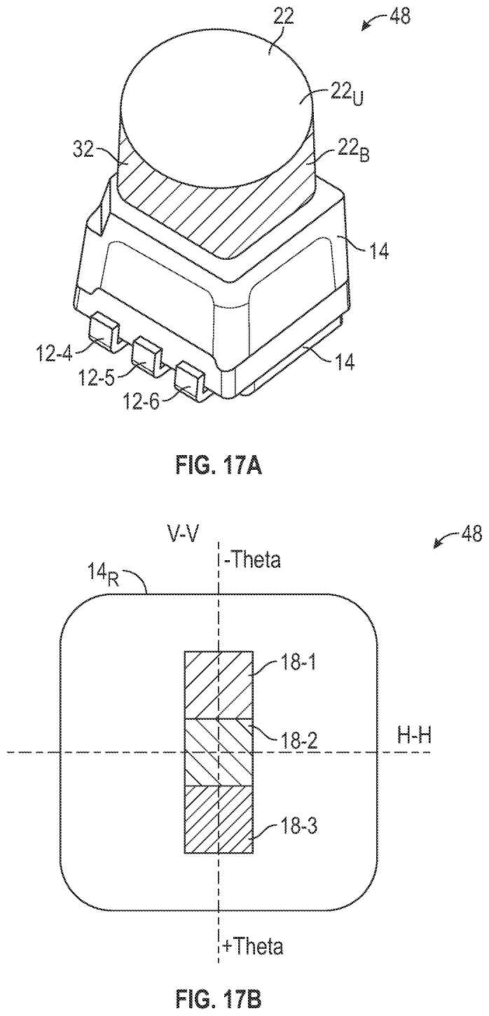

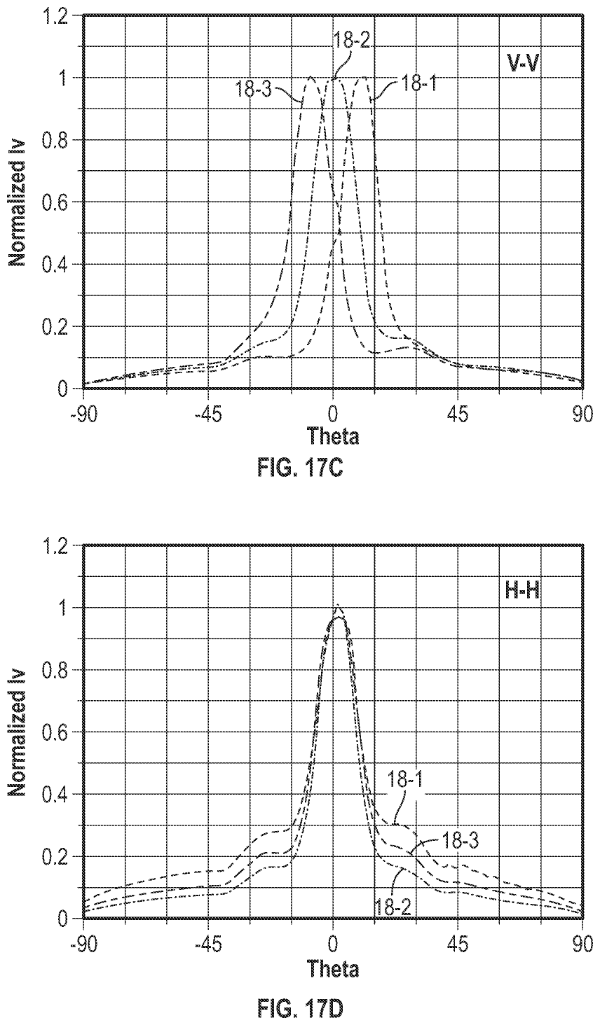

FIG. 17A is a top perspective view of an LED package 48 that is similar to the LED package 46 of FIGS. 16A and 16B but with the cladding layer 32 positioned along the lens base 22_{B}. The cladding layer 32 is arranged on the lens base 22_{B} to extend up from the housing 14 and along sidewalls of the lens 22 up to the lens upper portion 22_{U} of the lens 22. In this regard, the cladding layer 32 may be defined by parameters as illustrated in FIGS. 4 and 9-11 where the cladding layer 32-1 covers the lens base 22_{B} defined by the height i and the height n=0. Dimensions of the lens 22 and the cladding layer 32 are the same as described above for the LED package 44 of FIGS. 15A and 15B. FIG. 17B is a top view illustration representing positioning of LED chips 18-1 to 18-3 within the single recess 14_{R} of the housing 14 of FIG. 17A.

FIG. 17C is a graph of a far field pattern of the LED package 48 of FIGS. 17A and 17B along the V-V direction. In FIG. 17C, the y-axis represents a relative light intensity (i.e., normalized luminous intensity Iv) while the x-axis represents theta values along the V-V direction of FIG. 17B. With the presence of the cladding layer 32 and rectellipse shape of the lens 22, emission peaks and theta offsets for the LED chips 18-1 and 18-3 are similar to FIG. 16C. However, the LED chips 18-1 and 18-3 exhibited significantly decreased wider angle emission variations or impurities relative to FIG. 17C due to the presence of the cladding layer 32. For the LED package 48, FWHM values are less than 20° or no greater than 18° for all LED chips 18-1 to 18-3.

FIG. 17D is a graph of a far field pattern of the LED package 48 of FIGS. 17A and 17B along the H-H direction. In FIG. 17D, the y-axis represents a relative light intensity (i.e., normalized luminous intensity Iv) while the x-axis represents theta values along the H-H direction of FIG. 17D. As illustrated, emissions for the LED chips 18-1 and 18-3 exhibit significant decreased off-peak artifacts in the H-H direction as compared with FIG. 16D. Again, the presence of the cladding layer 32 effectively redirects wide angle emission light.

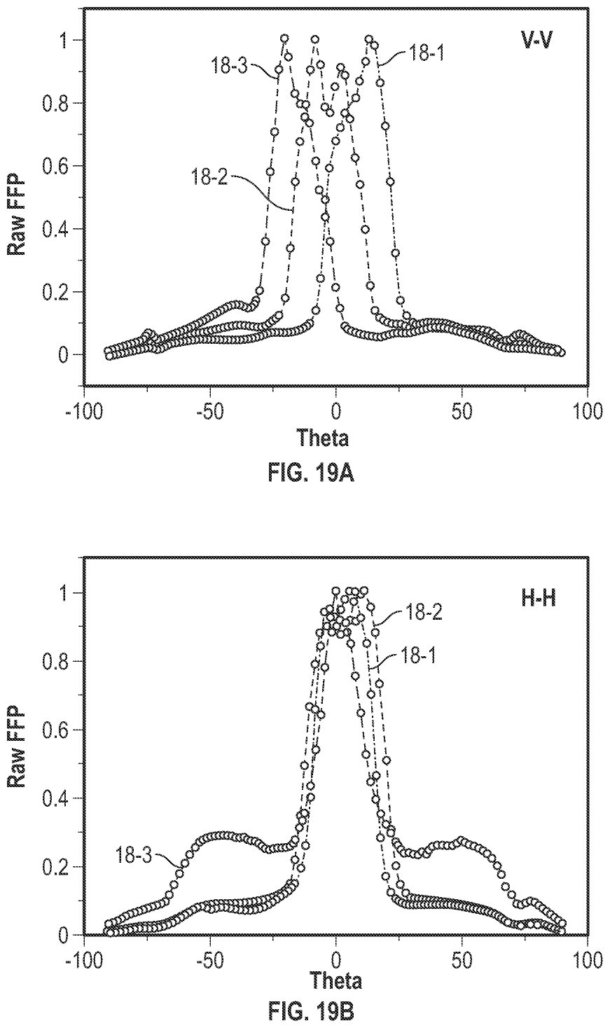

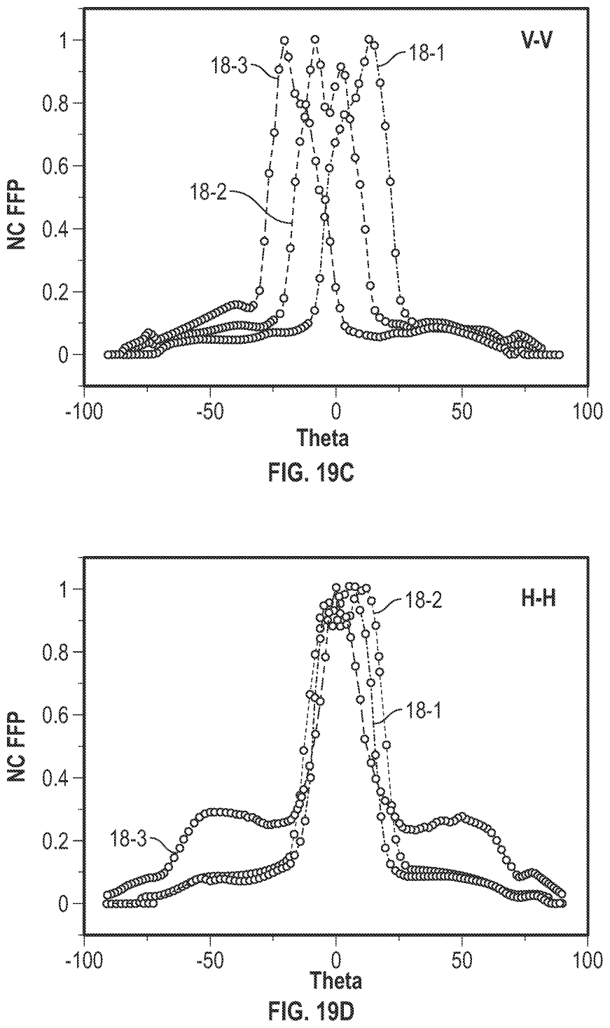

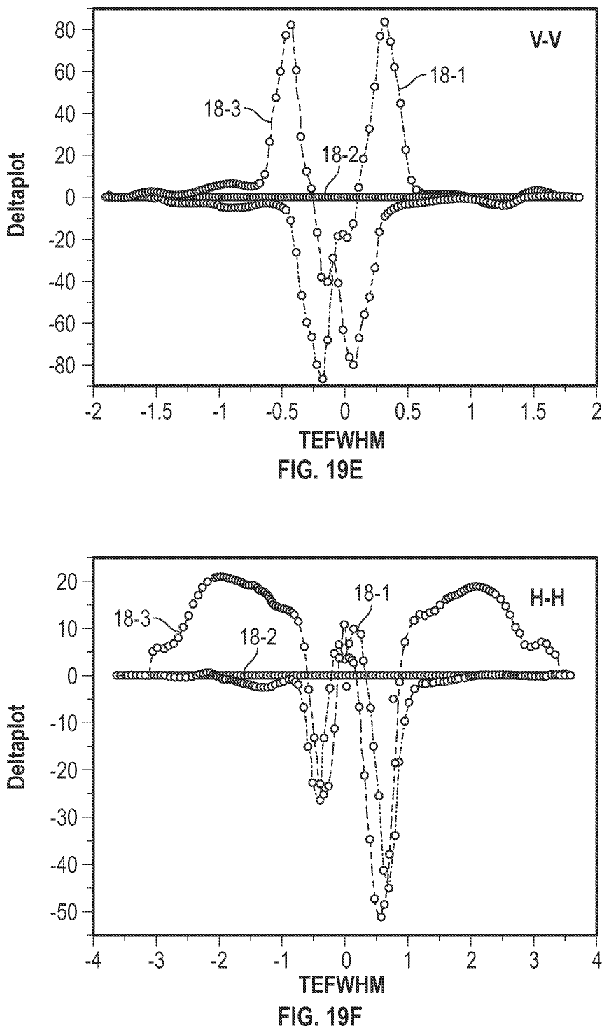

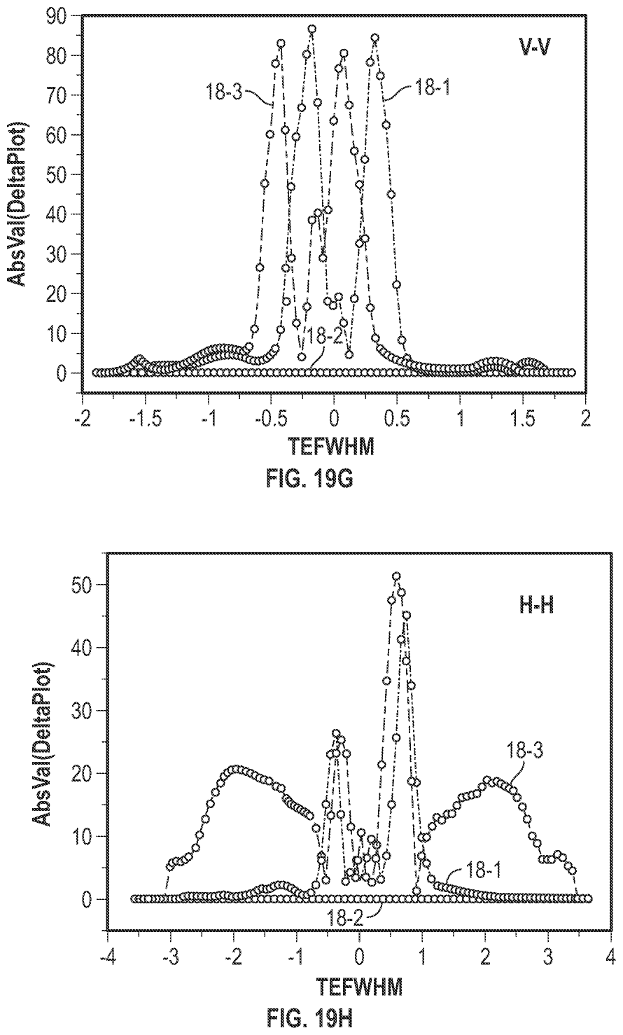

According to aspects of the present disclosure, evaluation parameters have been developed to compare uniformity and color mixing in far field patterns for LED packages of the present disclosure. As disclosed herein, a figure of merit (FOM) is developed to define a color quality index metric that characterizes color quality and uniformity of far field emissions in multiple-color and multiple-chip LED packages. For example, a FOM for a color quality index as described herein may be useful for characterizing red, green, and blue wavelength peaks from an LED package containing a red LED chip, a blue LED chip, and a green LED chip. For the purpose of visualizing FOM in various graphs, a reference total envelope full width half maximum (TEFWHM_{Ref}) is first determined for multiple-chip LED emissions. While not being a constituent of the FOM, the TEFWHM_{Ref} is generated as a way to normalize the x-axis (e.g., theta angle) in order to visualize and compare different emission delta patterns to each other. The TEFWHM_{Ref} corrects for viewing angle to provide the envelope where the intensity of each color is above 50% at a given theta. The TEFWHM_{Ref} may then be used to generate various graphs for the FOM in order to compare various arrangements of LED chip layouts, lens dimensions and shapes, and/or cladding layers according to principles of the present disclosure. As described here, the FOM is derived by evaluating emission peaks from multiple LED chips in a far field pattern relative to a centered peak in the far field pattern (viewing angle of 0° from center) by determining and integrating areas under the curve for all absolute values of noise corrected deviations from center, deriving a ratio of the sum of areas under the curve to all possible values, and normalizing to a minimum-maximum range of 0 to 1. As indicated above, TEFWHM_{Ref} is used to visualize the graphs of FIGS. 19A-19F, but the actual calculation of the FOM is independent of TEFWHM_{Ref} number.

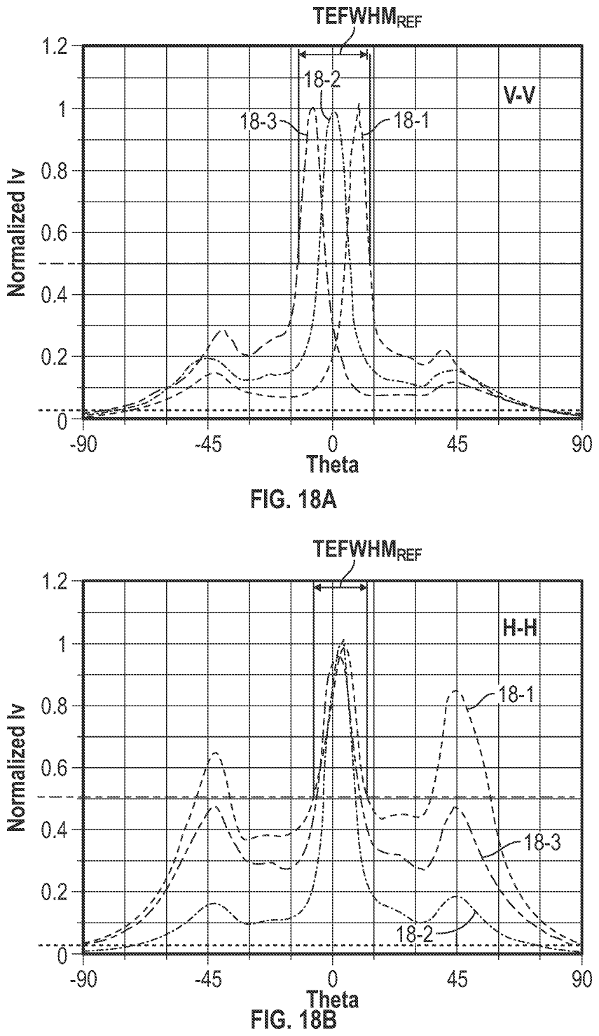

FIG. 18A is a graph of an exemplary far field pattern of FIG. 14C in the V-V direction and further illustrating the TEFWHM_{Ref} relative to the overall emissions from the LED chips 18-1 to 18-3. FIG. 18B is a graph of an exemplary far field pattern of FIG. 14D in the H-H direction and further illustrating the TEFWHM_{Ref} relative to the overall emissions from the LED chips 18-1 to 18-3. The selection of data from FIGS. 14C and 14D is for exemplary purposes to illustrate TEFWHM_{Ref} for any LED package. To generate the plot lines for each LED chip 18-1 to 18-3, raw far field pattern inputs for normalized luminous intensity (Iv) vs theta (θ) are collected. From the data, a LEFT (L) plot line is defined as a most negative θ value (i.e., 18-3), a CENTER (C) plot line is defined as θ=0 for the center peak wavelength (i.e., 18-2), and a RIGHT (R) plot line is defined as the most positive θ value (i.e., 18-1). Inputs for primary peak TEFWHM_{Ref} may then be defined as the maximum negative theta (θₘᵢₙ) and the maximum positive theta (max) for vertical (V-V) and horizontal (H-H) directions where the normalized luminous intensity is at 50% (Iv(θ)=0.5). In FIGS. 18A and 18B, horizontal dashed lines are drawn where Iv(θ)=0.5 and vertical lines indicate corresponding boundaries of TEFWHM_{Ref}.

Noise correction for raw far field patterns (NoiseLVL) may then be applied for a noise level appropriate for features in the data to capture all ancillary peaks and emissions while baselining other values for model simplicity. For example, the noise level is set to Iv(θ)=0.05 for FIGS. 18A and 18B so that Iv(θ)<0.05 becomes Iv(θ)=0. In practice, the noise level may be set to other levels based on relative noise in various far field patterns. The TEFWHM_{Ref} value for normalizing theta (θ) in the H-H and V-V directions may be defined by adding absolute values for the maximum negative theta (θₘᵢₙ) and the maximum positive theta (θₘₐₓ) with the following equations.

$${HorzTEFWHM}_{Ref} = \vert Horz {θ}_{max} \vert + \vert Horz {θ}_{min} \vert$$

$${VertTEFWHM}_{Ref} = \vert Vert {θ}_{max} \vert + \vert Vert {θ}_{min} \vert$$

In FIGS. 18A and 18B, horizontal dashed lines are drawn where Iv(θ)=0.5 and vertical lines indicate corresponding boundaries defining TEFWHM_{Ref}.

Subsequently, x-axis values for theta (θ) may now be corrected with the TEFWHM_{Ref} such that the H-H values of theta (θ) are normalized with the HorzTEFWHM_{Ref} and the V-V values of theta (θ) are normalized with the VertTEFWHM_{Ref}, resulting in new x-axis values defined as the normalized TEFWHM as shown in FIG. 19E to 19H.

$$For H - H : TEFWHM = \frac{θ}{Horz {TEFWHM}_{Ref}}$$

$$For V - V : TEFWHM = \frac{θ}{VertTEFWH {M}_{Ref}}$$

Noise corrected intensity values (IvNC(θ)) may be derived by the following conditional equation.

$$IvNC ( θ ) = \{ \begin{matrix}Iv ( θ ) , Iv ( θ ) \geq NoiseLVL \\ 0 , Iv ( θ ) < NoiseLVL\end{matrix}$$

Noise corrected intensity value percentage (IvNC % (θ)) for all non-zero values may be derived by the following conditional equation.

$$InNC \% ( θ ) = \{ \begin{matrix}( IvNC {( θ )}_{L E F T} - IvN {C ( θ )}_{C E N T E R} ) \times 100 , & IvNC ( θ ) \neq 0 \\ 0 , & IvNC ( θ ) = 0\end{matrix}$$

Absolute values for IvNC % (θ) may then be defined as |IvNC % (θ)| for all LEFT, CENTER, and RIGHT plot lines in both V-V and H-H directions for a total of six plot lines.

A net intensity factor (IvNCSumAll) may then be defined for each plot line by integrating the area under the curve over all |IvNC % (θ)| contributions for a total quantifiable metric of optical quality deviation or delta from the CENTER far field pattern over all θ values. The formula ∫|IvNC % (θ)| dθ may be implemented for LEFT and RIGHT plot lines in both V-V and H-H directions. Functionally, this is achieved with a sum of all |IvNC % (θ)| for all θ values for LEFT and RIGHT plot lines in both V-V and H-H directions by the follow equation.

$${\sum }_{V V \vert H H} {\sum }_{L \vert R} \vert IvNC \% ( θ ) \vert = IvNCSumALL$$

CENTER plot line values are omitted since they are by definition all zero and are non-contribution to this portion. A net intensity factor ratio may then be defined by the following ratio where IvNCSumALL_{Max} refers to a maximum possible value for IvNCSumAll.

$$IvNCSu {m}_{Ratio} = 1 - \frac{IvNCSumALL}{IvNCSumAL {L}_{Max}}$$

The FOM may then be generated by normalizing the net intensity factor ratio (IvNCSum_{Ratio}). By way of example, for a data collection with 91 data points per far field pattern scan for LEFT and RIGHT plot lines in both V-V and H-H directions, the IvNCSumALL_{Max}=36400. The 91 data points represent 91 for LEFT V-V, RIGHT V-V, LEFT H-H, and RIGHT H-H where center points of 0 are omitted. The FOM may then be evaluated as the net intensity factor ratio normalized to a minimum ratio to expand the range (0 to 1) and thereby defined by the following equation.

$$FOM = \frac{IvNCSu {m}_{R a t i o} - min ( IvNCSu {m}_{Ratio} )}{1 - min ( IvNCSu {m}_{Ratio} )}$$

The max (IvNCSum_{Ratio}) is by definition 1 and the min (IvNCSum_{Ratio}) is set to 0.6 for reference low range, based on an overall structure of the LED package 38 of FIGS. 12A to 12-D.

As described above, for an LED package with multiple LED chips generating multiple peak wavelengths, the FOM for a far field pattern of the LED chips defines a color quality index for uniformity of the far field pattern relative to a center peak wavelength. The FOM of the far field pattern may be defined as a function of: (1) raw far field pattern data for each LED chip; (2) a noise corrected luminous intensity data of the raw far field pattern data for each LED chip; (3) a percent difference relative to the center peak wavelength for all nonzero noise corrected luminous intensity data; (4) areas under a curve for all absolute values of the percent difference relative to the center peak wavelength; and (5) a ratio of the areas under the curve to all possible values normalized to a minimum-maximum range of 0 to 1, where the ratio is normalized based on a minimum reference of 0.6.

As described herein, the FOM may then be used to compare and/or classify LED packages by their respective designs, symmetry, and target FWHM values. Various classification designs may include single cavity or multiple cavity LED packages with and without curved lenses. Comparisons by ranking FOM within classifications may then be achieved. For example, FOM may be ranked for various LED packages having single cavity and symmetric designs for a particular target FWHM. In another example, FOM may be ranked for various LED packages having multiple cavity and asymmetric designs at another target FWHM.

FIGS. 19A to 19H are plots representing generation of FOM for the LED package 40 of FIGS. 13A to 13D as described by the above equations. The selection of LED package 40 is for exemplary purposes to illustrate generation of FOM for any LED package. FIG. 19A is a graph of the V-V direction far field pattern of FIG. 13C in raw data format. FIG. 19B is a graph of the H-H direction far field pattern of FIG. 13D in raw data format. FIG. 19C is a graph with the data from FIG. 19A with noise corrected far field pattern (NC FFP) in the V-V direction. FIG. 19D is a graph with the data from FIG. 19C with noise corrected far field pattern (NC FFP) in the H-H direction. In this regard, FIGS. 19C and 19D represent the noise corrected intensity value (IvNC(θ)) described above.

Next, the noise corrected intensity value percentage IvNC % (θ) relative to CENTER is determined and plotted. FIG. 19E is a graph illustrating the delta from CENTER, or IvNC % (θ), by normalized TEFWHM values for the plot lines of FIG. 19C in the V-V direction. FIG. 19F is a graph illustrating the delta from CENTER, or IvNC % (θ), by normalized TEFWHM values for the plot lines of FIG. 19D in the H-H direction. In both FIGS. 19E and 19F, the plot lines for the LED chip 18-2 are zeroed since the other plot lines 18-1 and 18-3 represent optical quality deviations from the FFP of the centrally positioned LED chip 18-2.

FIG. 19G is a graph illustrating absolute values |IvNC % (θ)| for the plot lines of FIG. 19E, and FIG. 19H is a graph illustrating absolute values |IvNC % (θ)| for the plot lines of FIG. 19F. Next, the net intensity factor (IvNCSumAll) for a quantifiable metric of optical quality deviation or delta from CENTER far field pattern may be determined as described above based on the absolute values |IvNC % (θ)|. Finally, the FOM may be derived by defining a ratio of the net intensity factor IvNCSumAll to the maximum possible value IvNCSumALL_{Max} and normalizing as described by the FOM equation above.

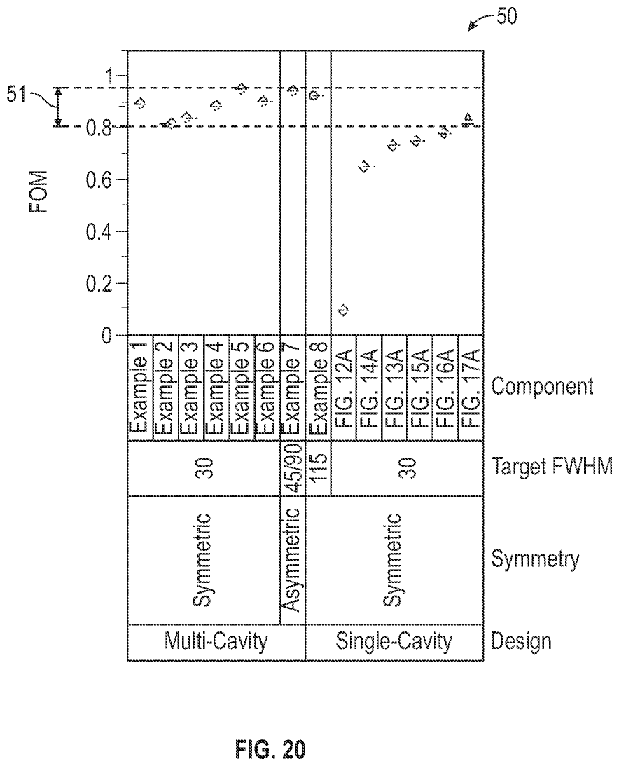

FIG. 20 is a summary table 50 illustrating FOM, or normalized ratios, for various LED package configurations. As described above, the FOM as described herein is essentially an RGB color quality index metric that characterizes color quality and uniformity of far field emissions for multiple-color and multiple-chip LED packages. In FIG. 20, Examples 1 to 7 represent conventional multiple cavity LED packages where a red LED chip, a blue LED chip, and a green LED chip are arranged in separate cavities. Examples 1 to 6 represent symmetric LED packages with FWHM targets of 30°, and Example 7 represents an asymmetric LED package with directional emission FWHM targets of 45° and 90°. Example 8 represents a conventional single cavity LED package with a red LED chip, a blue LED chip, and a green LED chip and no curved lens (i.e., a flat top encapsulant within the recess) with a FWHM target of 115°. Examples 1-8 are provided as reference for comparison with the single cavity and lensed LED packages of the present disclosure that target narrower FWHM values, such as 30°. A region 51 is illustrated with FOM values between 0.8 and 0.96 to represent industry accepted target FOM values.

As further illustrated in FIG. 20, FOM values for the LED packages as described above for FIGS. 12A to 17A are also provided. The FOM of the LED package 38 of FIG. 12A is very low, indicative of optical effects of having a curved lens over multiple LED chips in a single cavity, where only one LED chip can be centered relative to the lens. The FOM of the LED package 40 of FIG. 13A and the LED package 42 of FIG. 14A is improved by reducing the spacing between the LED chips and/or increasing a height of the lens; however, the FOM values remain below the industry accepted region 51. Notably, the FOM of the LED package 44 of FIG. 15A is highest among lenses with round bases (i.e., FIGS. 12A to 15A) due to the contributions of the cladding layer 32. As further illustrated, the rectellipse lens base for the LED package 46 of FIG. 16A and the LED package 48 of FIG. 17A provided even higher FOM values. Notably, the addition of the cladding layer for the LED package 48 of FIG. 17A provided an FOM value above 0.8 and within the industry accepted region 51 of 0.8 to 0.96. Accordingly, aspects of the present disclosure provide multiple-chip in single cavity LED package arrangements with narrow FWHM targets (e.g., less than 60°, or 30° or less), with FOM values in a range from 0.7 to 0.96, or in a range from 0.8 to 0.96.

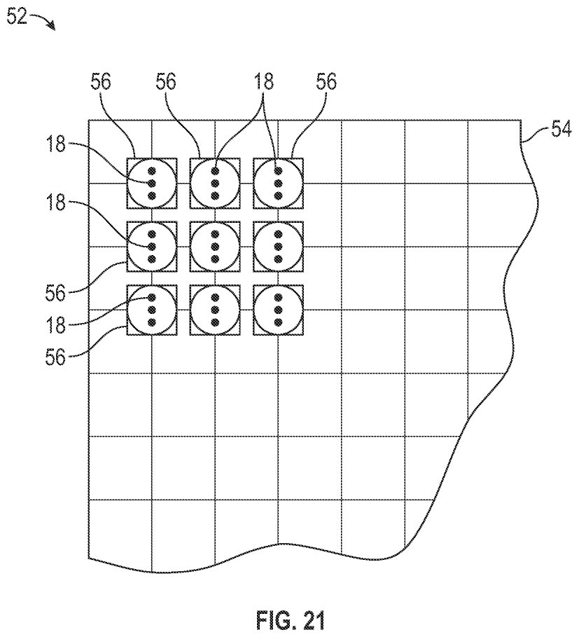

FIG. 21 is a schematic diagram of a portion of an LED display screen 52, that is, for example, an indoor and/or outdoor screen comprising, in general terms, a display panel including a driver PCB 54 carrying a large number of surface-mount devices (SMDs) 56 arranged in rows and columns, each SMD 56 defining a pixel. The SMDs 56 may comprise LED packages with LED chips 18 as described above for any of the embodiments shown in FIGS. 1A-17D. The SMDs 56 are electrically connected to traces or pads on the PCB 54 to respond to appropriate electrical signal processing and driver circuitry (not shown). As disclosed above, it is to be appreciated that while FIG. 21 depicts the LED chips 18 in a linear arrangement, in other embodiments, the LED chips 18 may be arranged in different configurations, such as the triangular layout of FIG. 3. By forming light mixing arrangements for multiple-chips in single recesses for the SMDs 56 as described above for any of FIGS. 1A-17D, pixels of the LED display screen may exhibit increased uniformity in far field patterns, particularly for lower FWHM applications. Accordingly, the LED display screen 52 may exhibit improved color rendering and contrast compared with conventional LED display screens.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure forming a recess;
one or more LED chips within the recess;
a lens over the recess; and
a cladding layer on a portion of the lens that is above the support structure, the cladding layer forming a coating on a surface of the lens.

2. The LED package of claim 1, wherein the lens comprises a lens base that extends from the support structure and a lens upper portion that forms a curved surface above the lens base.

3. The LED package of claim 2, wherein the lens base forms a circular cross-section.

4. The LED package of claim 2, wherein the lens base forms a rectellipse cross-section.

5. The LED package of claim 2, wherein the cladding layer is positioned on a surface of the lens along the lens base.

6. The LED package of claim 5, wherein the surface of the lens along the lens base where the cladding layer is positioned is spaced from a topmost surface of the support structure.

7. The LED package of claim 5, further comprising an additional cladding layer on a surface of the lens along the lens upper portion.

8. The LED package of claim 1, wherein the cladding layer comprises a light-reflective material.

9. The LED package of claim 1, wherein the cladding layer comprises a light-absorbing material.

10. The LED package of claim 1, wherein the one or more LED chips comprise at least three LED chips configured to generate a plurality of peak wavelengths, and the lens comprises a lens base that extends from the support structure and a lens upper portion that forms a curved surface above the lens base.

11. The LED package of claim 10, wherein a far field pattern of aggregate emissions from the at least three LED chips has a full width half maximum of less than 50.

12. The LED package of claim 11, wherein a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of:
raw far field pattern data for each LED chip;
a noise corrected luminous intensity data of the raw far field pattern data for each LED chip;
a percent difference relative to center for all nonzero noise corrected luminous intensity data;
areas under a curve for all absolute values of the percent difference relative to the center peak wavelength; and
a ratio of the areas under the curve to all possible values normalized to a minimum-maximum range of 0 to 1, where the ratio is normalized based on a minimum reference of 0.6.

13. The LED package of claim 12, wherein the FOM is in a range from 0.8 to 0.96.

14. The LED package of claim 1, wherein the support structure comprises a lead frame at least partially encased in a housing.

15. A light-emitting diode (LED) package comprising:
a support structure forming a recess;
a lens over the recess, the lens comprising a lens base that extends from the support structure and a lens upper portion that forms a curved surface above the lens base; and
a plurality of LED chips within the recess, wherein a far field pattern of aggregate emissions from the plurality of LED chips has a full width half maximum of less than 60.

16. The LED package of claim 15, wherein the lens base forms a circular cross-section.

17. The LED package of claim 16, wherein the lens base forms a rectellipse cross-section.

18. The LED package of claim 15, further comprising a first cladding layer on a surface of the lens along the lens base.

19. The LED package of claim 18, wherein the first cladding layer comprises a light-reflective material.

20. The LED package of claim 18, wherein the first cladding layer comprises a light-absorbing material.

21. The LED package of claim 18, further comprising a second cladding layer on a surface of the lens along the lens upper portion.

22. The LED package of claim 15, wherein:
the plurality of LED chips comprises at least three LED chips configured to generate a plurality of peak wavelengths; and
a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of:
raw far field pattern data for each LED chip;
a noise corrected luminous intensity data of the raw far field pattern data for each LED chip;
a percent difference relative to the center peak wavelength for all nonzero noise corrected luminous intensity data;
areas under a curve for all absolute values of the percent difference relative to the center peak wavelength; and
a ratio of the areas under the curve to all possible values normalized to a minimum-maximum range of 0 to 1, where the ratio is normalized based on a minimum reference of 0.6.

23. The LED package of claim 22, wherein the FOM is in a range from 0.8 to 0.96.

24. The LED package of claim 15, wherein the full width half maximum is 30 or less.

25. The LED package of claim 15, wherein the support structure comprises a lead frame at least partially encased in a housing.

26. A light-emitting diode (LED) display comprising:
a display panel; and
at least one LED package comprising:
a support structure forming a recess;
a lens over the recess, the lens comprising a lens base that extends from the support structure and a lens upper portion that forms a curved surface above the lens base; and
a plurality of LED chips within the recess, wherein a far field pattern of aggregate emissions from the plurality of LED chips has a full width half maximum of less than 60.

27. The LED display of claim 26, wherein the full width half maximum is 40 or less.

28. The LED display of claim 26, further comprising a cladding layer on a surface of the lens along the lens base, the cladding layer comprising a light-reflective material or a light-absorbing material.

29. The LED display of claim 26, wherein:
the plurality of LED chips comprises at least three LED chips configured to generate a plurality of peak wavelengths; and
a figure of merit (FOM) for the far field pattern is in a range from 0.7 to 0.96, the FOM defining a color quality index for uniformity of the far field pattern relative to a center peak wavelength of the plurality of peak wavelengths, wherein the FOM is a function of:
raw far field pattern data for each LED chip;
a noise corrected luminous intensity data of the raw far field pattern data for each LED chip;
a percent difference relative to the center peak wavelength for all nonzero noise corrected luminous intensity data;
areas under a curve for all absolute values of the percent difference relative to the center peak wavelength; and
a ratio of the areas under the curve to all possible values normalized to a minimum-maximum range of 0 to 1, where the ratio is normalized based on a minimum reference of 0.6.

30. The LED display of claim 29, wherein the FOM is in a range from 0.8 to 0.96.

31. The LED display of claim 26, wherein the support structure comprises a lead frame at least partially encased in a housing.
